(19) United States
(12) Patent Application Publication
(10) Pub. No.: US 2025/0040223 A1
(43) Pub. Date: Jan. 30, 2025

(54) SEMICONDUCTOR DEVICE

(71) Applicant: ROHM CO., LTD., Kyoto-shi (JP)

(72) Inventor: Masatsugu YUTANI, Kyoto-shi (JP)

(73) Assignee: ROHM CO., LTD., Kyoto-shi (JP)

(21) Appl. No.: 18/918,253

(22) Filed: Oct. 17, 2024

Related U.S. Application Data
(63) Continuation of application No. PCT/JP2023/008033, filed on Mar. 3, 2023.

(30) Foreign Application Priority Data
Apr. 21, 2022 (JP) 2022-070179

(51) Int. Cl. H01L 29/40; H01L 29/06; H01L 29/78

(52) U.S. Cl. CPC H01L 29/407; H01L 29/0696; H01L 29/7813

(57) ABSTRACT

A semiconductor device according to the present invention is provided with a gate trench that is formed in a semiconductor layer, and a gate electrode that is embedded in the gate trench, with an insulating layer interposed therebetween. The gate trench includes a first outer peripheral gate trench section that is provided in an outer peripheral region thereof, and a second outer peripheral gate trench section that is provided outward of the first outer peripheral gate trench section. The semiconductor device is provided with, in the semiconductor layer, a first floating trench that is formed in a region between the first outer peripheral gate trench section and the second outer peripheral gate trench section, and a first floating electrode that is embedded in the first floating trench, with an insulating layer interposed therebetween, and that is in an electrically floating state.

### CROSS-REFERENCE TO RELATED APPLICATIONS

This application is a continuation of, and claims the benefit of priority from International Application No. PCT/JP2023/008033, filed on Mar. 3, 2023, which claims the benefit of priority from Japanese Patent Application No. 2022-070179, filed on Apr. 21, 2022, the entire contents of each of which are incorporated herein by reference.

### BACKGROUND

### 1. Field

The present disclosure relates to a semiconductor device.

### 2. Description of Related Art

Japanese Laid-Open Patent Publication No. 2020-194881 discloses a semiconductor device including a trench-gate metal-oxide-semiconductor field-effect-transistor (MOSFET) as a basic structure. The semiconductor device includes an active region set in a region covered with a source electrode, a gate trench formed in the active region, and a polysilicon gate embedded in the gate trench.

### BRIEF DESCRIPTION OF DRAWINGS

FIG. 1 is a schematic plan view showing an exemplary semiconductor device according to a first embodiment.

FIG. 2 is a schematic plan view showing a metal layer of the semiconductor device shown in FIG. 1.

FIG. 3 is a schematic plan view showing a structure formed on a semiconductor layer of the semiconductor device shown in FIG. 1.

FIG. 4 is an enlarged partial view of the region indicated by F4 shown in FIG. 3.

FIG. 5 is a schematic cross-sectional view of the semiconductor device taken along line F5-F5 in FIG. 4.

FIG. 6 is a schematic cross-sectional view of the semiconductor device taken along line F6-F6 in FIG. 4.

FIG. 7 is an enlarged partial view of the region indicated by F7 shown in FIG. 6.

FIG. 8 is an enlarged partial view of the region indicated by F8 shown in FIG. 6.

FIG. 9 is a graph showing the relationship of drain-source breakdown voltage with the distance between a second floating trench and a protective trench.

FIG. 10 is a graph showing the relationship of drain-source breakdown voltage with the distance between a first peripheral gate trench portion and a first floating trench.

FIG. 11 is a graph showing the relationship of drain-source breakdown voltage with the distance between a second peripheral gate trench portion and the first floating trench.

FIG. 12 is an enlarged partial view of a schematic planar structure of a semiconductor layer in a comparative example of a semiconductor device.

FIG. 13 is a graph showing the I-V characteristics of the semiconductor device in the comparative example.

FIG. 14 is a graph showing the I-V characteristics of the semiconductor device in the first embodiment.

FIG. 15 is an enlarged partial view of a schematic planar structure of a semiconductor layer in a second embodiment of a semiconductor device.

FIG. 16 is a schematic cross-sectional view of the semiconductor device taken along line F16-F16 in FIG. 15.

FIG. 17 is an enlarged partial view of the region indicated by F17 shown in FIG. 16.

FIG. 18 is a graph showing the relationship of drain-source breakdown voltage with the distance between the first floating trench and the second floating trench.

FIG. 19 is a graph showing the relationship of drain-source breakdown voltage with the distance between a peripheral gate trench portion and the first floating trench.

FIG. 20 is a graph showing the I-V characteristics of the semiconductor device in the second embodiment.

### DETAILED DESCRIPTION

Embodiments of a semiconductor device in accordance with the present disclosure will now be described with reference to the accompanying drawings. Elements in the drawings are illustrated for simplicity and clarity and are not necessarily drawn to scale. In a cross-sectional view, hatching may be omitted to facilitate understanding. The accompanying drawings only illustrate embodiments of the present disclosure and are not intended to limit the present disclosure.

The following detailed description includes exemplary embodiments of a device, a system, and a method according to the present disclosure. The detailed description is illustrative and is not intended to limit embodiments of the present disclosure or the application and use of the embodiments.

### First Embodiment

### Planar Layout of Semiconductor Device

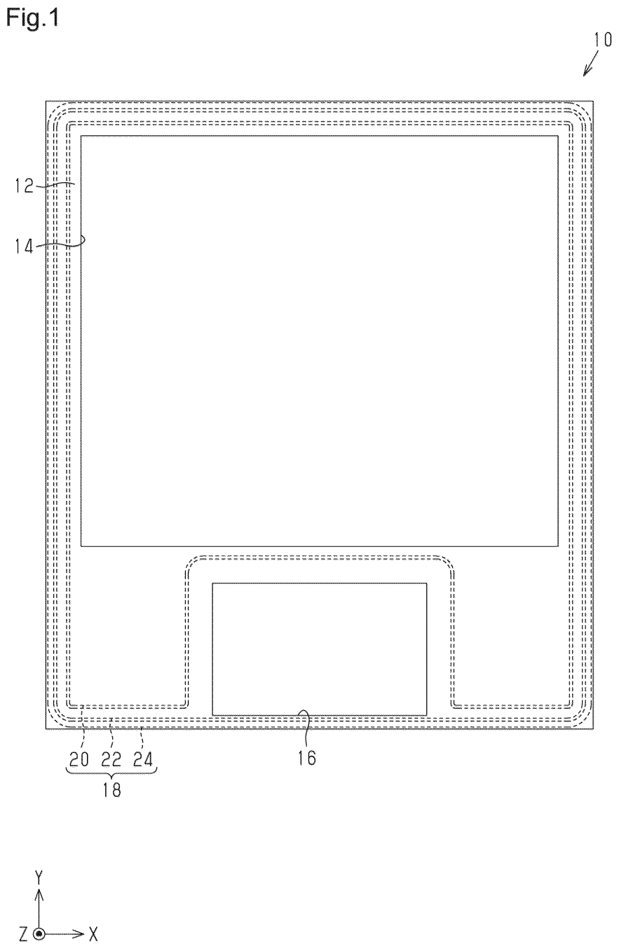

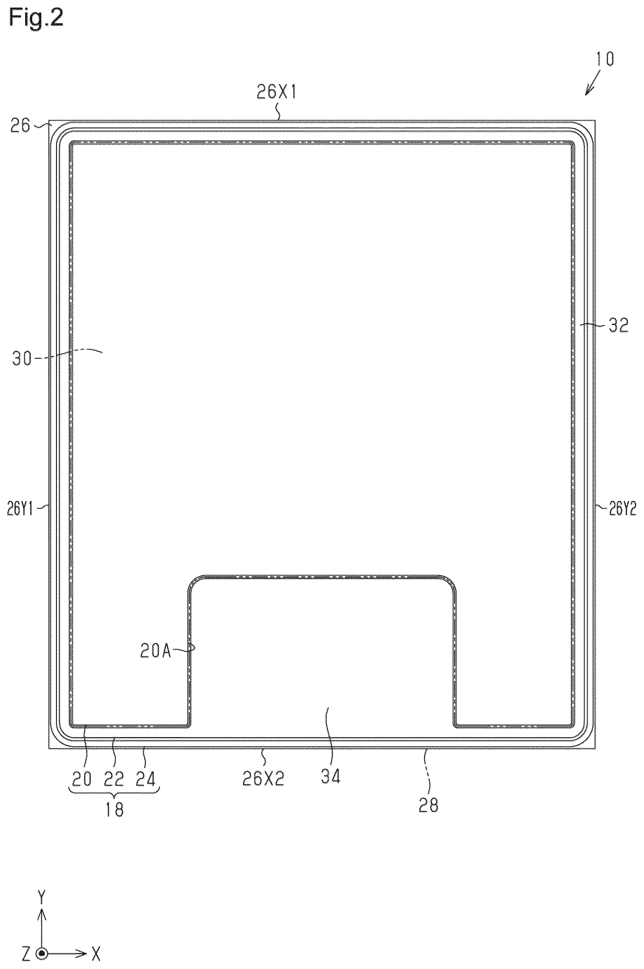

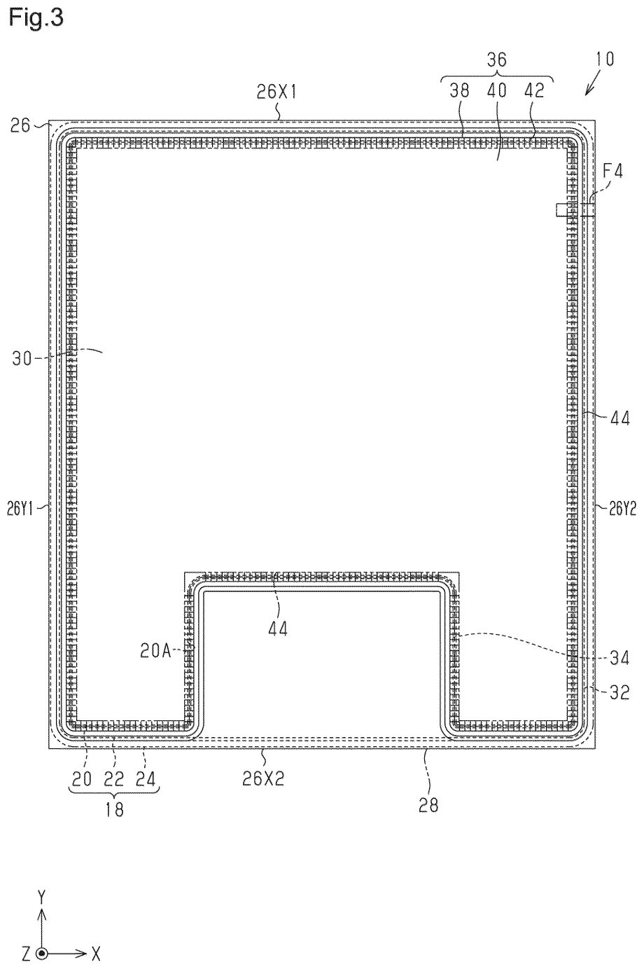

FIGS. 1 to 3 are each a schematic plan view of a semiconductor device 10 according to a first embodiment. Some of the elements of the semiconductor device 10 shown in FIG. 1 are transparently shown in FIGS. 2 and 3. More specifically, FIG. 2 is a schematic plan view of the semiconductor device 10 in which a passivation layer 12 shown in FIG. 1 is transparent. The passivation layer 12 will be described later. FIG. 3 is a schematic plan view of the semiconductor device 10 in which a metal layer 18 (source interconnect 20, gate interconnect 22, and peripheral electrode 24) shown in FIG. 2 is transparent. The metal layer 18 will be described later. To facilitate understanding, the metal layer 18 is indicated by broken lines in FIG. 3. Also, to facilitate understanding of the drawings, a first floating trench 52A and a second floating trench 52B, which will be described later, are omitted in FIGS. 1 to 3.

The X-axis, Y-axis, and Z-axis are orthogonal to one another as shown in FIG. 1. The term “plan view” as used in the present disclosure is a view of the semiconductor device 10 taken in the Z-axis direction. The term “plan view” will refer to a view taken from above along the Z-axis of the semiconductor device 10 unless otherwise indicated.

As shown in FIG. 1, the semiconductor device 10 may be rectangular in plan view. In an example, the semiconductor device 10 may have the form of a rectangular box. In an example, the semiconductor device 10 may have the form of a flat plate having a thickness in the Z-axis direction. The semiconductor device 10 may include a passivation layer 12. The passivation layer 12 may be formed from any material that protects structures located under the passivation layer 12. The passivation layer 12 may be formed of, for example, a silicon nitride (SiN) film. The passivation layer 12 may have pad openings 14 and 16. The material forming the passivation layer 12 may be changed in any manner. In an example, the passivation layer 12 may be formed of silicon oxide (SiO₂) film. The passivation layer 12 may have a stacking structure including the SiN film and SiO₂ film.

The semiconductor device 10 may further include a metal layer 18. The passivation layer 12 at least partially covers the metal layer 18. The metal layer 18 may be formed from at least one of titanium (Ti), nickel (Ni), gold (Au), silver (Ag), copper (Cu), aluminum (Al), a Cu alloy, and an Al alloy. In an example, the metal layer 18 may be formed from an AlCu alloy.

The metal layer 18 may include a source interconnect 20, a gate interconnect 22, and a peripheral electrode 24. The source interconnect 20, the gate interconnect 22, and the peripheral electrode 24 are separated from each other. The gate interconnect 22 is separated from the source interconnect 20 and surrounds the source interconnect 20. The peripheral electrode 24 is separated from the gate interconnect 22 and surrounds the gate interconnect 22. The source interconnect 20, the gate interconnect 22, and the peripheral electrode 24 will be further described later in detail with reference to FIG. 2.

The pad opening 14 may expose at least a portion of the source interconnect 20. The pad opening 16 may expose at least a portion of the gate interconnect 22. The pad openings 14 and 16 may be arranged to allow for connection of the source interconnect 20 and the gate interconnect 22 with an external element. The peripheral electrode 24 may be completely covered by the passivation layer 12. The configuration (e.g., position, shape, size, number) of the pad openings 14 and 16 may be determined in accordance with, for example, the design and usage of the semiconductor device 10 and thus is not limited to the example shown in FIG. 1.

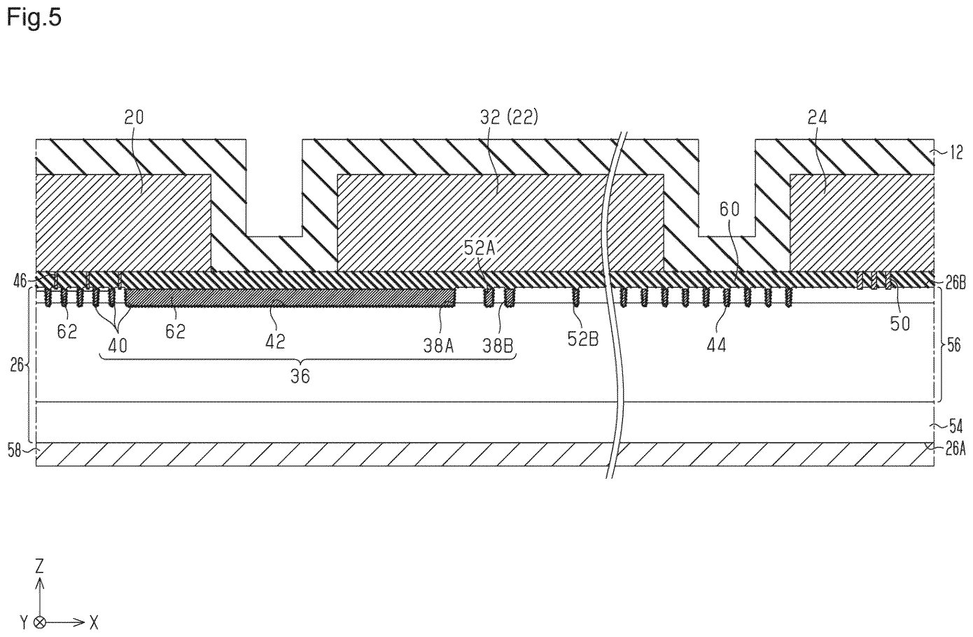

As shown in FIG. 2, the semiconductor device 10 may include a semiconductor layer 26. The metal layer 18 may be formed on the semiconductor layer 26. The semiconductor layer 26 includes a first surface 26A and a second surface 26B opposite to the first surface 26A (refer to FIG. 5). The Z-axis direction shown in FIG. 2 corresponds to a direction that is orthogonal to the first surface 26A and the second surface 26B of the semiconductor layer 26.

The semiconductor layer 26 may be formed from at least one of silicon (Si), silicon carbide (SiC), and gallium nitride (GaN). In an example, the semiconductor layer 26 may be formed from Si. The second surface 26B of the semiconductor layer 26 includes two sides 26X1 and 26X2 extending in the X-axis direction and two sides 26Y1 and 26Y2 extending in the Y-axis direction. In plan view, the edge of the semiconductor layer 26 may include the four sides 26X1, 26X2, 26Y1, and 26Y2. The region of the semiconductor layer 26 defined by the four sides 26X1, 26X2, 26Y1, 26Y2 may correspond to a single chip (die).

In plan view, the semiconductor layer 26 may include a peripheral region 28 and an active region 30 surrounded by the peripheral region 28. In FIG. 2, the boundary between the peripheral region 28 and the active region 30 is indicated by double-dashed lines.

The active region 30 is a region that contributes to operation of the semiconductor device 10 as a transistor. The peripheral region 28 is a region that does not contribute to operation of the semiconductor device 10 as a transistor. The peripheral region 28 may include the four sides 26X1, 26X2, 26Y1, and 26Y2 defining the edge of the semiconductor layer 26. In plan view, the peripheral region 28 may have the form of a rectangular frame surrounding the active region 30. The semiconductor layer 26 will be described later further in detail with reference to FIG. 5.

The source interconnect 20 may include a substantially rectangular cutaway portion in plan view, defining a recess 20A. The recess 20A may be formed in an end of the source interconnect 20 located in the proximity of one of the four sides 26X1, 26X2, 26Y1, and 26Y2 of the semiconductor layer 26. In the example shown in FIG. 2, the recess 20A may be formed in a center of the source interconnect 20 in the X-axis direction located in the proximity of the side 26X2 of the semiconductor layer 26. The recess 20A may be open toward the side 26X2.

The gate interconnect 22 may include a gate finger 32 and a gate pad 34. The gate finger 32 may be arranged in the peripheral region 28. The gate finger 32 may extend along at least a portion of the four sides 26X1, 26X2, 26Y1, and 26Y2 of the semiconductor layer 26 to surround at least a portion of the source interconnect 20. The gate pad 34 may be arranged in the peripheral region 28. The gate pad 34 may be arranged at least partially in the recess 20A of the source interconnect 20. The gate pad 34 may be integrally connected to the gate finger 32. In the example shown in FIG. 2, the gate pad 34 may be arranged to connect two portions of the gate finger 32 extending along the side 26X2 in plan view.

In plan view, the peripheral electrode 24 may be closed-loop-shaped. The peripheral electrode 24 may extend along the four sides 26X1, 26X2, 26Y1, and 26Y2 of the semiconductor layer 26. The peripheral electrode 24 may be separated from the four sides 26X1, 26X2, 26Y1, and 26Y2 of the semiconductor layer 26.

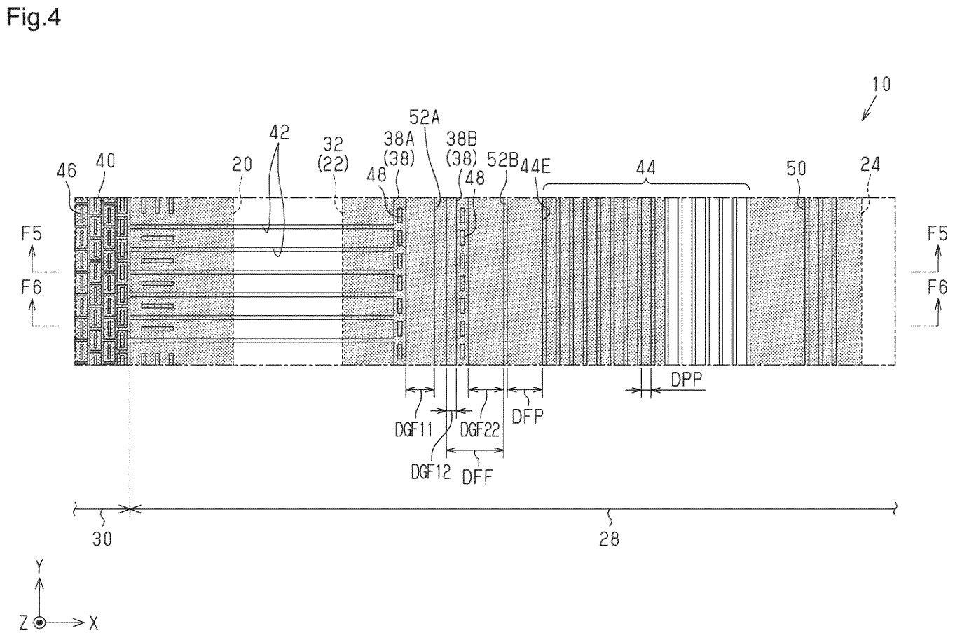

FIG. 3 is a schematic view of some elements formed in the semiconductor layer 26. The semiconductor device 10 may further include a gate trench 36 formed in the semiconductor layer 26. The gate trench 36 is formed in both the peripheral region 28 and the active region 30 of the semiconductor layer 26. The gate trench 36 may include a peripheral gate trench portion 38 arranged in the peripheral region 28, an inner gate trench portion 40 (refer to FIG. 4) arranged in the active region 30, and a connection gate trench portion 42 connecting the peripheral gate trench portion 38 to the inner gate trench portion 40.

In plan view, the active region 30 may overlap the source interconnect 20. The active region 30 may be similar in shape to the source interconnect 20 including the recess 20A in plan view. The active region 30 may be slightly smaller than the source interconnect 20 including the recess 20A in plan view. The active region 30 is covered by the source interconnect 20 but is not covered by the gate pad 34. The inner gate trench portion 40 may be arranged in the active region 30. Thus, the inner gate trench portion 40 may overlap the source interconnect 20 in plan view. The connection gate trench portion 42 connected to the inner gate trench portion 40 may partially overlap the source interconnect 20 in plan view.

The peripheral region 28 may be similar in shape to the gate finger 32 and the gate pad 34 in plan view. In plan view, the peripheral region 28 may include a region extending into the recess 20A of the source interconnect 20. The peripheral region 28 is covered by the gate finger 32 and the gate pad 34.

The peripheral gate trench portion 38 arranged in the peripheral region 28 may be shaped to surround the source interconnect 20. In an example, in the peripheral region 28, the peripheral gate trench portion 38 may be similar in shape to the source interconnect 20 including the recess 20A in plan view. In plan view, the peripheral gate trench portion 38 may be slightly larger than the source interconnect 20 including the recess 20A. Thus, the peripheral gate trench portion 38 may have the form of a closed loop having a recess extending along the recess 20A in plan view. The peripheral gate trench portion 38 is arranged so as not to overlap the gate finger 32 and the gate pad 34 in plan view. Also, the peripheral gate trench portion 38 is arranged so as not to overlap the source interconnect 20 in plan view. In other words, the peripheral gate trench portion 38 is arranged between the source interconnect 20 and the gate finger 32 and between the source interconnect 20 and the gate pad 34 in plan view.

The semiconductor device 10 may further include a protective trench 44 formed in the semiconductor layer 26. The protective trench 44 may surround the peripheral gate trench portion 38. The protective trench 44 may be similar in shape to the peripheral gate trench portion 38 in plan view. In other words, the peripheral gate trench portion 38 is surrounded by the protective trench 44 in plan view. The semiconductor device 10 may include multiple protective trenches 44.

### Layout of Gate Trench and Protective Trench Around Gate Finger

FIG. 4 is an enlarged partial view of FIG. 3 showing section F4 surrounded by single-dashed line in FIG. 3. To facilitate understanding, in FIG. 4, the source interconnect 20, the gate interconnect 22 (gate finger 32), and the peripheral electrode 24 are provided with stippling.

As shown in FIG. 4, the inner gate trench portion 40 may be arranged in the active region 30 in a grid pattern. The semiconductor device 10 may further include a source contact 46 connected to the source interconnect 20. The source contact 46 may be arranged in rectangular regions of the semiconductor layer 26 surrounded by the inner gate trench portion 40. In another example, the inner gate trench portion 40 may have, for example, the form of stripes.

The peripheral gate trench portion 38 arranged in the peripheral region 28 may include the first peripheral gate trench portion 38A and the second peripheral gate trench portion 38B arranged outward from the first peripheral gate trench portion 38A. In other words, in plan view, the second peripheral gate trench portion 38B and the active region 30 are arranged at opposite sides of the first peripheral gate trench portion 38A. In other words, in plan view, the second peripheral gate trench portion 38B is arranged farther from the active region 30 than the first peripheral gate trench portion 38A is. In other words, the first peripheral gate trench portion 38A is located closer to the active region 30 than the second peripheral gate trench portion 38B is. The first peripheral gate trench portion 38A is mathematically similar to the second peripheral gate trench portion 38B in plan view.

Each of the peripheral gate trench portions 38A and 38B may be greater in width than the inner gate trench portion 40. The width of the first peripheral gate trench portion 38A refers to a dimension in a direction that is orthogonal to the direction in which the first peripheral gate trench portion 38A extends in plan view. The width of the first peripheral gate trench portion 38A may be referred to as a dimension in a direction in which the short sides of the first peripheral gate trench portion 38A extend in plan view. For example, in FIG. 4, the first peripheral gate trench portion 38A extends in the Y-axis direction and thus has a width in the X-axis direction. In the same manner, the width of the second peripheral gate trench portion 38B refers to a dimension in a direction that is orthogonal to the direction in which the second peripheral gate trench portion 38B extends in plan view. The width of the second peripheral gate trench portion 38B may be referred to as a dimension in a direction in which the short sides of the second peripheral gate trench portion 38B extend in plan view. For example, in FIG. 4, the second peripheral gate trench portion 38B extends in the Y-axis direction and thus has a width in the X-axis direction. In the same manner, the width of the inner gate trench portion 40 refers to a dimension in a direction that is orthogonal to the direction in which the inner gate trench portion 40 extends in plan view. That is, the width of the inner gate trench portion 40 may be referred to as a dimension in a direction in which the short sides of the inner gate trench portion 40 extend in plan view.

The semiconductor device 10 may further include a gate contact 48 connected to the gate interconnect 22 (gate finger 32). The gate contact 48 may be arranged in a region overlapping the peripheral gate trench portions 38A and 38B in plan view. The semiconductor device 10 may include multiple gate contacts 48.

The connection gate trench portion 42, which connects the first peripheral gate trench portion 38A to the inner gate trench portion 40, is arranged closer to the active region 30 than the first peripheral gate trench portion 38A is. The connection gate trench portion 42 is connected to the first peripheral gate trench portion 38A. The connection gate trench portion 42 is not connected to the second peripheral gate trench portion 38B. The connection gate trench portion 42 extends over both the peripheral region 28 and the active region 30. The connection gate trench portion 42 may extend in a direction (in FIG. 4, X-axis direction) that intersects a direction (in FIG. 4, Y-axis direction) in which the first peripheral gate trench portion 38A extends. Multiple connection gate trench portions 42 may be arranged in a strip pattern.

Multiple (in the example shown in FIG. 4, sixteen) protective trenches 44 are arranged in the peripheral region 28 and surround the peripheral gate trench portions 38A and 38B. The semiconductor device 10 may include one or more protective trenches 44. The number of protective trenches 44 may be set in accordance with the desired performance and layout of the semiconductor device 10. In the example shown in FIG. 4, the protective trenches 44 are arranged at an equal pitch. The arrangement of the protective trenches 44 may be changed in any manner. In an example, some of the protective trenches 44 may be arranged at different pitches.

As in the example shown in FIG. 4, when the protective trenches 44 are arranged, some of the protective trenches 44 may overlap the gate finger 32 in plan view. Alternatively, all of the protective trenches 44 may overlap the gate finger 32 in plan view.

The semiconductor device 10 may further include a peripheral contact 50 connected to the peripheral electrode 24. The peripheral contact 50 may be closed-loop-shaped. The loop-shaped peripheral contact 50 may surround the protective trench 44 in plan view. The semiconductor device 10 may include multiple peripheral contacts 50.

The source contact 46, the gate contact 48, and the peripheral contact 50 may be formed from any metal material. In an example, the contacts 46, 48, 50 may each be formed from at least one of tungsten (W), Ti, and titanium nitride (TiN).

The semiconductor device 10 may include the first floating trench 52A and the second floating trench 52B arranged between the connection gate trench portion 42 and the protective trench 44. The floating trenches 52A and 52B will be described later further in detail with reference to FIGS. 4 to 6 and 8.

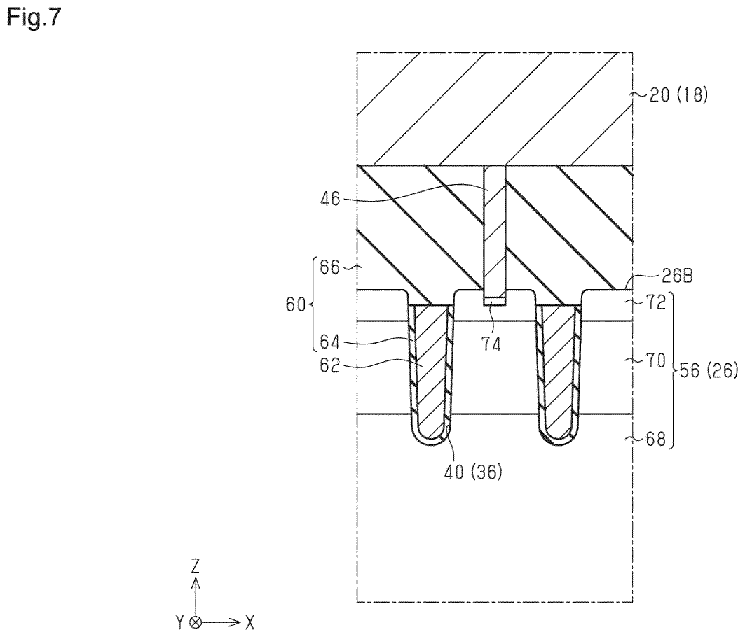

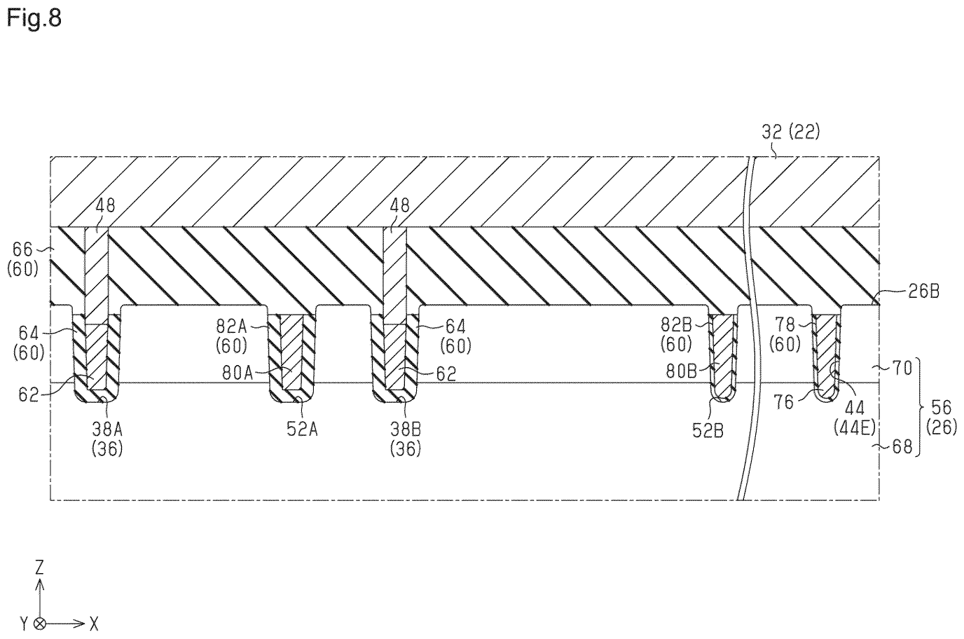

FIG. 5 is a schematic cross-sectional view of the semiconductor device 10 taken along line F5-F5 in FIG. 4. The semiconductor layer 26 may include a semiconductor substrate 54 and an epitaxial layer 56. The semiconductor substrate 54 includes the first surface 26A of the semiconductor layer 26. The epitaxial layer 56 is formed on the semiconductor substrate 54 and includes the second surface 26B of the semiconductor layer 26. In the present embodiment, the semiconductor substrate 54 may be a Si substrate. The semiconductor substrate 54 may correspond to a drain region of MISFET. The drain region (semiconductor substrate 54) may be a p⁺-type region including an p-type impurity. The concentration of the impurity in the semiconductor substrate 54 may be in a range of 1×10¹⁸cm⁻³ to 1×10²⁰ cm⁻³. The semiconductor substrate 54 may have a thickness that is in a range of 50 μm to 450 μm. The epitaxial layer 56 may be a Si layer epitaxially grown on the Si substrate. The epitaxial layer 56 will be described later further in detail with reference to FIGS. 7 and 8.

The semiconductor device 10 may further include a drain electrode 58 formed on the first surface 26A of the semiconductor layer 26. The drain electrode 58 is electrically connected to the drain region (semiconductor substrate 54). The drain electrode 58 may be formed from at least one of Ti, Ni, Au, Ag, Cu, Al, a Cu alloy, and an Al alloy.

The semiconductor device 10 may further include an insulation layer 60 formed on the semiconductor layer 26. The insulation layer 60 may be formed from, for example, SiO₂. Additionally or alternatively, the insulation layer 60 may include a film formed from an insulation material differing from SiO₂, which is, for example, SiN. The insulation layer 60 may have a stacking structure including the SiN film and the SiO₂ film.

The insulation layer 60 is in contact with the second surface 26B of the semiconductor layer 26. The source interconnect 20, the gate interconnect 22, and the peripheral electrode 24 are formed on the insulation layer 60. The passivation layer 12 covers at least a portion of the source interconnect 20, the gate interconnect 22, and the peripheral electrode 24 formed on the insulation layer 60. Further, the passivation layer 12 may cover a portion of the insulation layer 60 that is not covered by the source interconnect 20, the gate interconnect 22, and the peripheral electrode 24.

The gate trench 36 has an opening in the second surface 26B of the semiconductor layer 26 and has a depth in the Z-axis direction. In the same manner, the protective trench 44 also has an opening in the second surface 26B of the semiconductor layer 26 and has a depth in the Z-axis direction. In the example shown, the gate trench 36 and the protective trench 44 have substantially the same depth. However, in another example, the gate trench 36 and the protective trench 44 may each have a different depth. In an example, the protective trench 44 may have a greater depth than the gate trench 36 in the semiconductor layer 26. In another example, the protective trench 44 may have a smaller depth than the gate trench 36 in the semiconductor layer 26. In another example, the peripheral gate trench portions 38A and 38B and the inner gate trench portion 40 may each have a different depth. For example, the peripheral gate trench portions 38A and 38B may have a greater depth than the inner gate trench portion 40.

FIG. 5 is a cross-sectional view taken in the direction in which a connection gate trench portion 42 is elongated. The connection gate trench portion 42 includes two ends respectively connected to the first peripheral gate trench portion 38A and the inner gate trench portion 40. As described above, when the first peripheral gate trench portion 38A, the inner gate trench portion 40, and the connection gate trench portion 42 are connected to one another, and the second peripheral gate trench portion 38B is separated outward from the first peripheral gate trench portion 38A, the gate trench 36 is formed.

In each of the peripheral gate trench portions 38A and 38B, the inner gate trench portion 40, and the connection gate trench portion 42, a gate electrode 62 is embedded via the insulation layer 60. The gate electrode 62 will be described later with reference to FIGS. 7 and 8. Since the first peripheral gate trench portion 38A, the inner gate trench portion 40, and the connection gate trench portion 42 are connected to each other, the gate electrode 62 is integrally formed and is embedded over the first peripheral gate trench portion 38A, the inner gate trench portion 40, and the connection gate trench portion 42. Another gate electrode 62 differing from the integrally formed gate electrode 62 may be embedded in the second peripheral gate trench portion 38B.

The source contact 46 extends through the insulation layer 60, which is arranged between the source interconnect 20 and the semiconductor layer 26, to connect the source interconnect 20 and the semiconductor layer 26. The peripheral contact 50 extends through the insulation layer 60, which is arranged between the peripheral electrode 24 and the semiconductor layer 26, to connect the peripheral electrode 24 and the semiconductor layer 26.

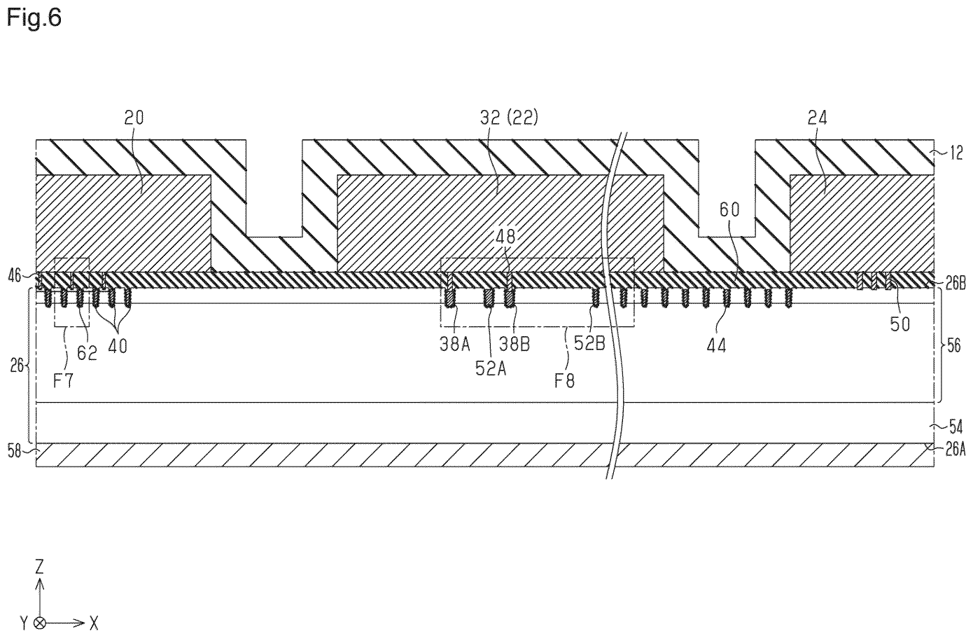

FIG. 6 is a schematic cross-sectional view of the semiconductor device 10 taken along line F6-F6 in FIG. 4 showing a region between two of the connection gate trench portions 42 that are located next to each other. Those elements shown in FIG. 6 that are the same as the corresponding elements in FIG. 5 will not be described in detail.

FIG. 6 shows the second peripheral gate trench portion 38B and a portion of the first peripheral gate trench portion 38A that is not directly connected to the connection gate trench portion 42. As described above and shown in the drawings, each of the peripheral gate trench portions 38A and 38B may be greater in width than the inner gate trench portion 40. In an example, the width of each of the peripheral gate trench portions 38A and 38B may be between 1.2 and 2.5 times, inclusive, of the width of the inner gate trench portion 40.

The gate contact 48 extends through the insulation layer 60 to connect the gate finger 32 and the gate electrode 62 embedded in the peripheral gate trench portions 38A and 38B (refer to FIG. 8). Thus, the gate interconnect 22 is electrically connected to the gate electrode 62.

FIG. 7 is an enlarged partial view of FIG. 6 showing section F7 surrounded by single-dashed line in FIG. 6. FIG. 7 is a cross-sectional view of the active region 30 (refer to FIG. 3).

The semiconductor device 10 may further include the gate electrode 62 embedded in the gate trench 36 via the insulation layer 60. The gate electrode 62 may be formed from, for example, a conductive polysilicon. The insulation layer 60 may include a gate insulation film 64 arranged between the gate electrode 62 and the semiconductor layer 26 to cover the gate trench 36 and an interlayer insulation film 66 formed between the metal layer 18 and the semiconductor layer 26. The gate electrode 62 is separated from the semiconductor layer 26 by the gate insulation film 64.

In FIG. 7, the gate insulation film 64 is arranged between the gate electrode 62 and the semiconductor layer 26 to cover the inner gate trench portion 40, and the interlayer insulation film 66 is arranged between the source interconnect 20 and the semiconductor layer 26.

The semiconductor layer 26 (epitaxial layer 56) may include a drift region 68, a body region 70 formed on the drift region 68, and a source region 72 formed on the body region 70. The source region 72 may include the second surface 26B of the semiconductor layer 26. The semiconductor layer 26 (epitaxial layer 56) may further include a contact region 74 located under the source contact 46. The source interconnect 20 is electrically connected to the contact region 74 by the source contact 46.

The drift region 68 may be a p⁻-type region containing a p-type impurity at a lower concentration than the drain region (semiconductor substrate 54). The impurity concentration of the drift region 68 may be in a range of 1×10¹⁵ cm⁻³ to 1×10¹⁸ cm⁻³. The drift region 68 may have a thickness in a range of 1 μm to 25 μm.

The body region 70 may be an n⁻-type region including an n-type impurity. The impurity concentration of the body region 70 may be in a range of 1×10¹⁶ cm⁻³ to 1×10¹⁸ cm⁻³. The body region 70 may have a thickness in a range of 0.5 μm to 1.5 μm.

The source region 72 may be a p⁺-type region including a p-type impurity at a higher concentration than the drift region 68. The impurity concentration of the source region 72 may be higher than that of the body region 70. The impurity concentration of the source region 72 may be in a range of 1×10¹⁹ cm⁻³ to 1×10²¹ cm⁻³. The source region 72 may have a thickness in a range of 0.1 μm to 1 μm.

The contact region 74 may be an n⁺-type region including an n-type impurity. The impurity concentration of the contact region 74 may be higher than that of the body region 70 and may be in a range of 1× 10¹⁹ cm⁻³ to 1×10²¹ cm⁻³.

In the present disclosure, p-type is referred to as a first conductive type, and n-type is referred to as a second conductive type. The p-type impurity may be, for example, boron (B) or aluminum (Al). The n-type impurity may be, for example, phosphorus (P) or arsenic (As).

The inner gate trench portion 40 has an opening in the second surface 26B of the semiconductor layer 26 and extends through the source region 72 and the body region 70 to the drift region 68. The side wall of the inner gate trench portion 40 may extend in a direction (Z-axis direction) orthogonal to the second surface 26B of the semiconductor layer 26. In the example shown, the inner gate trench portion 40 may include a side surface slightly inclined with respect to the Z-axis direction. In the example shown, the bottom wall of the inner gate trench portion 40 is entirely curved but is not limited to such a curvature. For example, the bottom wall of the inner gate trench portion 40 may be curved at two ends in the X-axis direction or may have a flat surface extending in the XY-plane.

When a predetermined voltage is applied to the gate electrode 62, a channel is formed in the n⁻-type body region 70, which is located adjacent to the gate insulation film 64. The semiconductor device 10 controls the flow of holes through the channel between the p⁺-type source region 72 and the p⁻-type drift region 68 in the Z-axis direction.

FIG. 8 is an enlarged partial view of FIG. 6 showing section F8 surrounded by single-dashed line in FIG. 6. FIG. 8 is a cross-sectional view showing the peripheral region 28 (refer to FIG. 3); particularly the region covered by the gate finger 32.

Each of the peripheral gate trench portions 38A and 38B has an opening in the second surface 26B of the semiconductor layer 26 and extends through the body region 70 to the drift region 68. The side wall of each of the peripheral gate trench portions 38A and 38B may extend in a direction (Z-axis direction) orthogonal to the second surface 26B of the semiconductor layer 26. In the example shown, the peripheral gate trench portions 38A and 38B may each include a side surface slightly inclined with respect to the Z-axis direction. In the example shown, the bottom wall of each of the peripheral gate trench portions 38A and 38B is curved at two ends in the X-axis direction but is not limited to such a curvature. For example, the bottom wall of each of the peripheral gate trench portions 38A and 38B may be entirely curved or may have a flat surface entirely extending in the XY-plane.

As described above, the gate electrode 62 is also embedded in each of the peripheral gate trench portions 38A and 38B via the insulation layer 60. Each of the peripheral gate trench portions 38A and 38B is greater in width than the inner gate trench portion 40. This allows the gate insulation film 64 to have a greater thickness in the peripheral gate trench portions 38A and 38B than in the inner gate trench portion 40. In this structure, the gate electrode 62 in the peripheral gate trench portion 38 may have the same thickness as the gate electrode 62 in the inner gate trench portion 40. Alternatively, the gate electrode 62 in each of the peripheral gate trench portions 38A and 38B may have a greater width than the gate electrode 62 in the inner gate trench portion 40 or may have a smaller width than the gate electrode 62 in the inner gate trench portion 40.

The gate contact 48 extends through the insulation layer 60 (interlayer insulation film 66) between the gate electrode 62 and the gate finger 32 to connect the gate electrode 62 embedded in each of the peripheral gate trench portions 38A and 38B to the gate finger 32.

The protective trench 44 may be separated from the peripheral gate trench portions 38A and 38B. When multiple protective trenches 44 are arranged, the protective trenches 44 may be separated from each other. The protective trench 44 may be arranged outward from the second peripheral gate trench portion 38B. The protective trench 44 is arranged to surround the second peripheral gate trench portion 38B. In other words, in plan view, the protective trench 44 and the active region 30 are arranged at opposite sides of the second peripheral gate trench portion 38B. In other words, in plan view, the protective trench 44 is arranged farther from the active region 30 than the second peripheral gate trench portion 38B is. In other words, in plan view, the second peripheral gate trench portion 38B is located closer to the active region 30 than the protective trench 44 is.

In the example shown, the protective trench 44 may have a smaller width than each of the peripheral gate trench portions 38A and 38B. In another example, the protective trench 44 may have the same width as each of the peripheral gate trench portions 38A and 38B or may have a greater width than each of the peripheral gate trench portions 38A and 38B.

The protective trench 44 may have the same width as the inner gate trench portion 40 (refer to FIG. 7). In another example, the protective trench 44 may have a smaller width than the inner gate trench portion 40 and a larger width than the inner gate trench portion 40.

The protective trench 44 has an opening in the second surface 26B of the semiconductor layer 26 and extends through the body region 70 to the drift region 68. The side wall of the protective trench 44 may extend in a direction (Z-axis direction) orthogonal to the second surface 26B of the semiconductor layer 26. In the example shown, the protective trench 44 may include a side surface slightly inclined with respect to the Z-axis direction. In the example shown, the bottom wall of the protective trench 44 is entirely curved but is not limited to such a curvature. For example, the bottom wall of the protective trench 44 may be curved at two ends in the X-axis direction or may have a flat surface extending in the XY-plane.

The semiconductor device 10 may further include a protective electrode 76 embedded in the protective trench 44 via the insulation layer 60. The protective electrode 76 may be formed from, for example, a conductive polysilicon. The protective trench 44 is closed-loop-shaped in plan view. Thus, the protective electrode 76 may also be closed-loop-shaped in plan view.

The insulation layer 60 may further include a protective insulation film 78 arranged between the protective electrode 76 and the semiconductor layer 26 to cover the protective trench 44. The protective electrode 76 is separated from the semiconductor layer 26 by the protective insulation film 78. The protective electrode 76 may be embedded in the protective trench 44 without being connected to other metal members (e.g., gate finger 32) and may be electrically floating. In an example, the protective electrode 76 may have the same width as the gate electrode 62 in the inner gate trench portion 40. Alternatively, the protective electrode 76 may have a greater width than the gate electrode 62 in the inner gate trench portion 40 or may have a smaller width than the gate electrode 62 in the inner gate trench portion 40.

As shown in FIG. 8, in a region other than the active region 30 (refer to FIG. 3), the semiconductor layer 26 does not include the source region 72 (refer to FIG. 7) and includes the drift region 68 and the body region 70. Thus, in the region shown in FIG. 8, the second surface 26B of the semiconductor layer 26 is included in the body region 70.

### Structure Between Connection Gate Trench Portion and Protective Trench 44

The structure between the connection gate trench portion 42 and the protective trench 44 will now be described with reference to FIGS. 4, 6, and 8. In the description hereafter, among the protective trenches 44, the protective trench 44 located closest to the second peripheral gate trench portion 38B is referred to as “end protective trench 44E.”

As shown in FIG. 4, the first floating trench 52A and the second floating trench 52B are arranged between the connection gate trench portion 42 and the protective trench 44. In the example shown in FIG. 4, the first floating trench 52A and the second floating trench 52B are alternately arranged with the first peripheral gate trench portion 38A and the second peripheral gate trench portion 38B.

More specifically, the first floating trench 52A is arranged between the first peripheral gate trench portion 38A and the second peripheral gate trench portion 38B. More specifically, the first floating trench 52A is arranged outward from the first peripheral gate trench portion 38A. In other words, in plan view, the first floating trench 52A and the active region 30 are arranged at opposite sides of the first peripheral gate trench portion 38A. In plan view, the first floating trench 52A is arranged farther from the active region 30 than the first peripheral gate trench portion 38A is.

The first floating trench 52A is arranged closer to the second peripheral gate trench portion 38B than to the first peripheral gate trench portion 38A. Thus, a distance DGF12 between the first floating trench 52A and the second peripheral gate trench portion 38B is less than a distance DGF11 between the first floating trench 52A and the first peripheral gate trench portion 38A. In an example, the distance DGF11 may be in a range of 1 μm to 10 μm. In an example, the distance DGF12 may be in a range of 1 μm to 4.6 μm. The relationship between the distance DGF12 and the distance DGF11 may be changed in any manner.

The second floating trench 52B is arranged outward from the second peripheral gate trench portion 38B. In other words, in plan view, the second floating trench 52B and the first floating trench 52A are arranged at opposite sides of the second peripheral gate trench portion 38B. In an example, the second floating trench 52B may be arranged between the second peripheral gate trench portion 38B and the end protective trench 44E. In the example shown in FIG. 4, the second floating trench 52B is arranged at the center between the second peripheral gate trench portion 38B and the end protective trench 44E. Thus, a distance DGF22 between the second peripheral gate trench portion 38B and the second floating trench 52B is equal to a distance DFP between the second floating trench 52B and the end protective trench 44E. In an example, the distance DGF22 may be in a range of 1 μm to 7 μm.

The position of the second floating trench 52B may be changed in any manner between the second peripheral gate trench portion 38B and the end protective trench 44E. In an example, the second floating trench 52B may be arranged closer to the second peripheral gate trench portion 38B than to the end protective trench 44E. In another example, the second floating trench 52B may be arranged closer to the end protective trench 44E than to the second peripheral gate trench portion 38B.

In the example shown in FIG. 4, the distance DGF12 is greater than a distance DPP between ones of the protective trenches 44 that are located next to each other. In an example, the distance DPP is 1 μm. Therefore, in the example shown in FIG. 4, the distance DGF12 is greater than 1 μm. In an example, the distance DGF12 is less than or equal to two times the distance DPP. In an example, the distance DGF12 is less than or equal to three times the distance DPP. The distance DGF12 may be equal to the distance DPP or may be less than the distance DPP.

In the example shown in FIG. 4, the distance DGF11 is greater than the distance DPP. In an example, the distance DGF11 is greater than or equal to two times the distance DPP. The relationship between the distance DGF11 and the distance DPP may be changed in any manner. In an example, the distance DGF11 is greater than or equal to three times the distance DPP. In an example, the distance DGF11 is greater than or equal to four times the distance DPP. In an example, the distance DGF11 is greater than or equal to five times the distance DPP. In an example, the distance DGF11 is greater than or equal to six times the distance DPP. In an example, the distance DGF11 is greater than or equal to seven times the distance DPP. In an example, the distance DGF11 is greater than or equal to eight times the distance DPP. In an example, the distance DGF11 is greater than or equal to nine times the distance DPP. In an example, the distance DGF11 is less than or equal to ten times the distance DPP.

The distance DGF11 may be less than the distance DGF22 between the second peripheral gate trench portion 38B and the second floating trench 52B. Also, the distance DGF12 may be less than the distance DGF22.

In another example, the distance DGF11 may be equal to the distance DGF22 or may be greater than the distance DGF22. Also, in another example, the distance DGF12 may be equal to the distance DGF22 or may be greater than the distance DGF22.

The distance DGF11 may be greater than the distance DFP between the second floating trench 52B and the end protective trench 44E. In another example, the distance DGF11 may be equal to the distance DFP or may be less than the distance DFP.

The distance DGF22 may be equal to the distance DFP. In another example, the distance DGF22 may be greater than the distance DFP or may be less than the distance DFP. Each of the distance DGF22 and the distance DFP may be greater than the distance DPP.

A distance DFF between the first floating trench 52A and the second floating trench 52B is greater than the distance DPP between two of the protective trenches 44 that are located next to each other. The distance DFF is greater than the distance DGF12. The distance DFF is greater than the distance DGF11. The distance DFF is greater than the distance DFP.

In plan view, the first floating trench 52A may be shaped to surround the first peripheral gate trench portion 38A. In an example, the first floating trench 52A may be similar in shape to the first peripheral gate trench portion 38A in plan view. In plan view, the second peripheral gate trench portion 38B may be shaped to surround the first floating trench 52A. In an example, the second peripheral gate trench portion 38B may be similar in shape to the first floating trench 52A in plan view. Thus, the first floating trench 52A may be closed-loop-shaped in conformance with the shape of the recess 20A (refer to FIG. 2) in plan view.

In plan view, the second floating trench 52B may be shaped to surround the second peripheral gate trench portion 38B. In an example, the second floating trench 52B may be similar in shape to the second peripheral gate trench portion 38B in plan view. Thus, the second floating trench 52B may be closed-loop-shaped in conformance with the shape of the recess 20A in plan view.

The floating trenches 52A and 52B are arranged so as not to overlap the gate finger 32 and the gate pad 34 in plan view. Also, the floating trenches 52A and 52B do not overlap the source interconnect 20 in plan view. That is, the floating trenches 52A and 52B are arranged between the source interconnect 20 and the gate finger 32 and between the source interconnect 20 and the gate pad 34 in plan view.

As shown in FIGS. 5 and 6, the first floating trench 52A may have the same width as each of the peripheral gate trench portions 38A and 38B. That is, the first floating trench 52A may be greater in width than each of the inner gate trench portion 40 and the protective trench 44.

In another example, the first floating trench 52A may be greater in width than each of the peripheral gate trench portions 38A and 38B or may be less in width than each of the peripheral gate trench portions 38A and 38B. In another example, the first floating trench 52A may be equal in width to the inner gate trench portion 40 or may be less in width than the inner gate trench portion 40. In another example, the first floating trench 52A may be equal in width to the protective trench 44 or may be less in width than the protective trench 44.

The second floating trench 52B may be less in width than each of the peripheral gate trench portions 38A and 38B. In an example, the second floating trench 52B may be equal in width to the inner gate trench portion 40. The second floating trench 52B may be equal in width to the protective trench 44. That is, the second floating trench 52B is less in width than the first floating trench 52A. In other words, the first floating trench 52A is greater in width than the second floating trench 52B.

In another example, the second floating trench 52B may be equal in width to each of the peripheral gate trench portions 38A and 38B or may be greater in width than each of the peripheral gate trench portions 38A and 38B. In another example, the second floating trench 52B may be greater in width than the inner gate trench portion 40 or may be less in width than the inner gate trench portion 40. In another example, the second floating trench 52B may be greater in width than the protective trench 44 or may be less in width than the protective trench 44

As shown in FIGS. 5 and 6, the first floating trench 52A and the second floating trench 52B may have the same depth. The floating trenches 52A and 52B may have the same depth as the peripheral gate trench portions 38A and 38B. The floating trenches 52A and 52B may have the same depth as the inner gate trench portion 40 and the protective trench 44.

The depth of the floating trenches 52A and 52B may be changed in any manner. In an example, the first floating trench 52A may be greater in depth than the second floating trench 52B or may be less in depth than the second floating trench 52B. In another example, each of the floating trenches 52A and 52B may be greater in depth than each of the peripheral gate trench portions 38A and 38B or may be less in depth than each of the peripheral gate trench portions 38A and 38B. In another example, the floating trenches 52A and 52B may be greater in depth than the inner gate trench portion 40 or may be less in depth than the inner gate trench portion 40. In another example, the floating trenches 52A and 52B may be greater in depth than the protective trench 44 or may be less in depth than the protective trench 44.

As shown in FIG. 8, the first floating trench 52A has an opening in the second surface 26B of the semiconductor layer 26 and extends through the body region 70 to the drift region 68. The side wall of the first floating trench 52A may extend in a direction (Z-axis direction) orthogonal to the second surface 26B of the semiconductor layer 26. In the example shown, the first floating trench 52A may include a side surface slightly inclined with respect to the Z-axis direction. The bottom wall of the first floating trench 52A is curved at two ends in the X-axis direction but is not limited to such a curvature. For example, the bottom wall of the first floating trench 52A may be entirely curved or may have a flat surface extending in the XY-plane. In the example shown in FIG. 8, in the cross-sectional view of FIG. 8, the first floating trench 52A and the peripheral gate trench portions 38A and 38B have the same cross-sectional shape. However, the first floating trench 52A and the peripheral gate trench portions 38A and 38B may each have a different cross-sectional shape.

The second floating trench 52B has an opening in the second surface 26B of the semiconductor layer 26 and extends through the body region 70 to the drift region 68. The side wall of the second floating trench 52B may extend in a direction (Z-axis direction) orthogonal to the second surface 26B of the semiconductor layer 26. In the example shown, the second floating trench 52B may include a side surface slightly inclined with respect to the Z-axis direction. In the example shown, the bottom wall of the second floating trench 52B is entirely curved but is not limited to a such a curvature. For example, the bottom wall of the second floating trench 52B may be curved at two ends in the X-axis direction or may have a flat surface extending in the XY-plane. In the example shown in FIG. 8, in the cross-sectional view of FIG. 8, the second floating trench 52B and the protective trench 44 have the same cross-sectional shape. However, the second floating trench 52B and the protective trench 44 may each have a different cross-sectional shape.

The semiconductor device 10 may further include a first floating electrode 80A embedded in the first floating trench 52A via the insulation layer 60 and a second floating electrode 80B embedded in the second floating trench 52B via the insulation layer 60. In the present embodiment, the first floating electrode 80A corresponds to a “floating electrode.”

The floating electrodes 80A and 80B may be formed from, for example, a conductive polysilicon. The floating trenches 52A and 52B are similar in shape to the peripheral gate trench portions 38A and 38B in plan view. Thus, the floating electrodes 80A and 80B may be similar in shape to the peripheral gate trench portions 38A and 38B in plan view.

The insulation layer 60 may further include a first floating insulation film 82A and a second floating insulation film 82B. The first floating insulation film 82A is formed in the first floating trench 52A between the first floating electrode 80A and the semiconductor layer 26. The second floating insulation film 82B is formed in the second floating trench 52B between the second floating electrode 80B and the semiconductor layer 26. Thus, the first floating electrode 80A is separated from the semiconductor layer 26 by the first floating insulation film 82A. The second floating electrode 80B is separated from the semiconductor layer 26 by the second floating insulation film 82B. The floating electrodes 80A and 80B are not connected to other metal members (e.g., gate finger 32) and are electrically floating.

In the example shown in FIG. 8, the first floating trench 52A is equal in width to each of the peripheral gate trench portions 38A and 38B. Thus, the first floating insulation film 82A is equal in thickness to each of the gate insulation films 64 of the peripheral gate trench portions 38A and 38B. The first floating trench 52A is greater in width than the inner gate trench portion 40. Thus, the first floating insulation film 82A is greater in thickness than the gate insulation film 64 of the inner gate trench portion 40.

The second floating trench 52B is less in width than each of the peripheral gate trench portions 38A and 38B. Thus, the second floating insulation film 82B is less in thickness than each of the gate insulation films 64 of the peripheral gate trench portions 38A and 38B. In other words, the gate insulation films 64 of the peripheral gate trench portions 38A and 38B are each greater in thickness than the second floating insulation film 82B. The second floating trench 52B is equal in width to the inner gate trench portion 40. Thus, the second floating insulation film 82B is equal in thickness to the gate insulation film 64 of the inner gate trench portion 40.

The first floating trench 52A is greater in width than the second floating trench 52B. Thus, the first floating insulation film 82A is greater in thickness than the second floating insulation film 82B.

The first floating electrode 80A may be equal in width to the gate electrode 62 embedded in each of the peripheral gate trench portions 38A and 38B. The first floating electrode 80A may be equal in width to the gate electrode 62 and the protective electrode 76 embedded in the inner gate trench portion 40.

In another example, the first floating electrode 80A may be greater in width than the gate electrode 62 in each of the peripheral gate trench portions 38A and 38B or may be less in width than the gate electrode 62 in each of the peripheral gate trench portions 38A and 38B. In another example, the first floating electrode 80A may be greater in width than the gate electrode 62 in the inner gate trench portion 40 or may be less in width than the gate electrode 62 in the inner gate trench portion 40. In another example, the first floating electrode 80A may be greater in width than the protective electrode 76 or may be less in width than the protective electrode 76.

The second floating electrode 80B may be equal in width to the gate electrode 62 in each of the peripheral gate trench portions 38A and 38B. In an example, the second floating electrode 80B may be equal in width to the gate electrode 62 in the inner gate trench portion 40. The second floating electrode 80B may be equal in width to the protective electrode 76. The second floating electrode 80B may be equal in width to the first floating electrode 80A.

In another example, the second floating electrode 80B may be greater in width than the gate electrode 62 in each of the peripheral gate trench portions 38A and 38B or may be less in width than the gate electrode 62 in each of the peripheral gate trench portions 38A and 38B. In another example, the second floating electrode 80B may be greater in width than the gate electrode 62 in the inner gate trench portion 40 or may be less in width than the gate electrode 62 in the inner gate trench portion 40. In another example, the second floating electrode 80B may be greater in width than the protective electrode 76 or may be less in width than the protective electrode 76. In another example, the second floating electrode 80B may be less in width than the first floating electrode 80A. In other words, the first floating electrode 80A may be greater in width than the second floating electrode 80B. In another example, the second floating electrode 80B may be greater in width than the first floating electrode 80A.

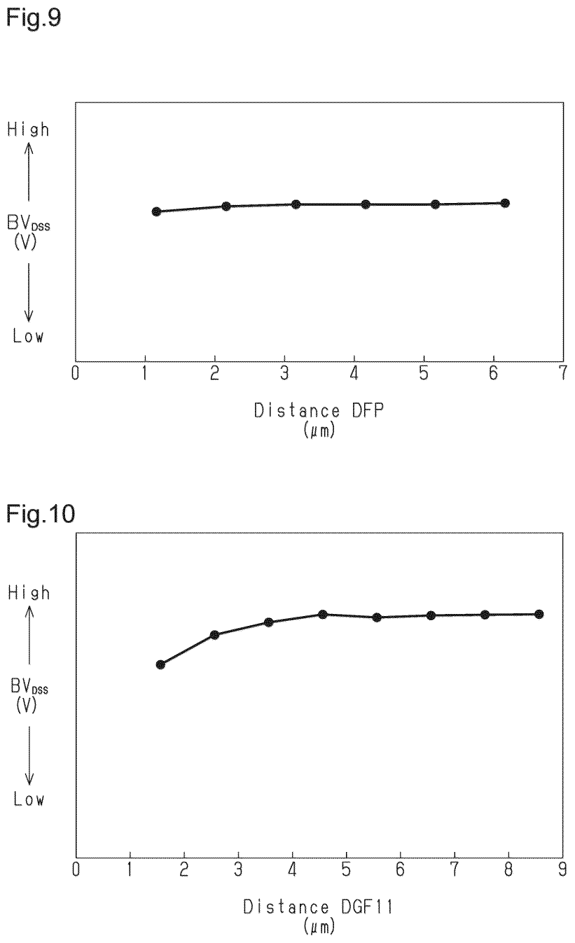

With reference to FIGS. 9 to 11, the relationship between the drain-source breakdown voltage (BV_{DSS}) and the positional relationship of the peripheral gate trench portions 38A and 38B with the floating trenches 52A and 52B will be described.

FIG. 9 is a graph showing the relationship of the drain-source breakdown voltage BV_{DSS} with the distance DFP between the second floating trench 52B and the end protective trench 44E.

As shown in FIG. 9, regardless of changes in the distance DFP, the drain-source breakdown voltage BV_{DSS} is substantially constant. When the distance DFP is less than 2.16μm, as the distance DFP decreases, the drain-source breakdown voltage BV_{DSS} slightly decreases. The result indicates that the distance DFP does not have a significant effect on the drain-source breakdown voltage BV_{DSS}. Hence, the distance DFP may be set in any manner. However, if even a slight decrease in the drain-source breakdown voltage BV_{DSS} is not tolerated, it is preferred that the distance DFP is set to be greater than or equal to 2.16 μm.

FIG. 10 is a graph showing the relationship of the drain-source breakdown voltage BV_{DSS} with the distance DGF11 between the first peripheral gate trench portion 38A and the first floating trench 52A when the distance DFP is set to 4.16 μm and the distance DGF12 between the second peripheral gate trench portion 38B and the first floating trench 52A is set to 4 μm.

As shown in FIG. 10, when the distance DGF11 is in a range of 1.56 μm to 4.56 μm, as the distance DGF11 increases, the drain-source breakdown voltage BV_{DSS} increases. When the distance DGF11 is greater than or equal to 4.56 μm, regardless of increases in the distance DGF11, the drain-source breakdown voltage BV_{DSS} is substantially constant. Hence, it is preferred that the distance DGF11 is greater than or equal to 4.56 μm. In this case, the distance DGF11 is greater than the distance DFP.

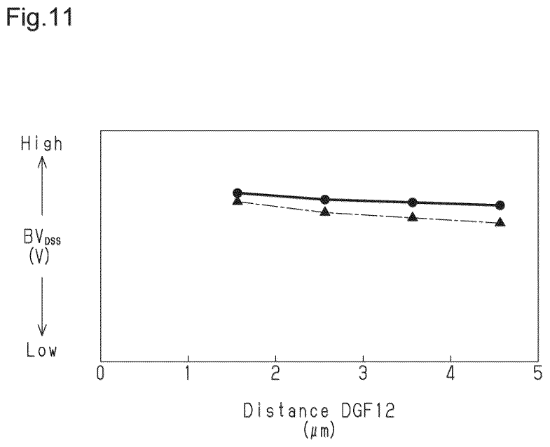

FIG. 11 is a graph showing the relationship of the distance DGF12 with the drain-source breakdown voltage BV_{DSS}. In the graph shown in FIG. 11, the solid line with the plot of black dots shows the relationship of the distance DGF12 with the drain-source breakdown voltage BV_{DSS} when the distance DGF11 is set to 3.56 μm. The single-dashed line with the plot of triangles shows the relationship of the distance DGF12 and the drain-source breakdown voltage BV_{DSS} when the distance DGF11 is set to 2.56 μm.

As shown in FIG. 11, for each of when the distance DGF11 is 2.56 μm and when the distance DGF11 is 3.56 μm, as the distance DGF12 increases, the drain-source breakdown voltage BV_{DSS} decreases. When the distance DGF11 is 3.56 μm, the drain-source breakdown voltage BV_{DSS} is always higher than when the distance DGF11 is 2.56 μm. The result indicates that it is preferred that the distance DGF11 is increased to increase the drain-source breakdown voltage BV_{DSS}. From the results shown in FIGS. 10 and 11, it is preferred that the first floating trench 52A is arranged closer to the second peripheral gate trench portion 38B than to the first peripheral gate trench portion 38A in order to increase the drain-source breakdown voltage BV_{DSS}.

### Operation

The operation of the semiconductor device 10 of the present embodiment will be described.

In the trench-gate MOSFET, the breakdown voltage between the drain and the source may be decreased, which is referred to as the walk-in phenomenon.

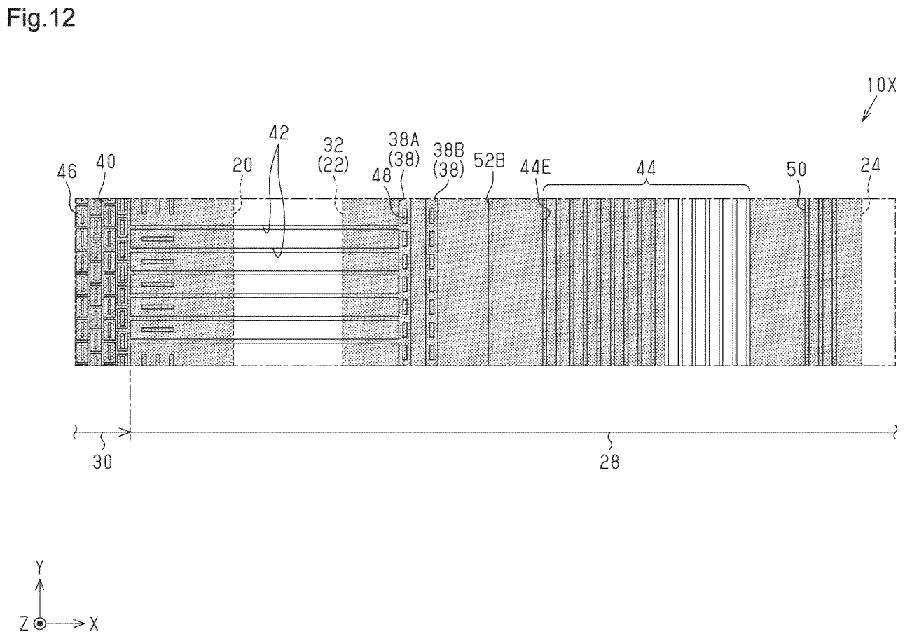

FIG. 12 is a schematic plan view showing a portion of a peripheral region 28 in a comparative example of a semiconductor device (hereafter, referred to as “the comparative semiconductor device 10X”)

As shown in FIG. 12, the comparative semiconductor device 10X has a structure such that the first floating trench 52A, the first floating electrode 80A, and the first floating insulation film 82A are omitted from the semiconductor device 10. In accordance with omission of the elements, the second peripheral gate trench portion 38B is arranged closer to the first peripheral gate trench portion 38A than the second peripheral gate trench portion 38B of the present embodiment is.

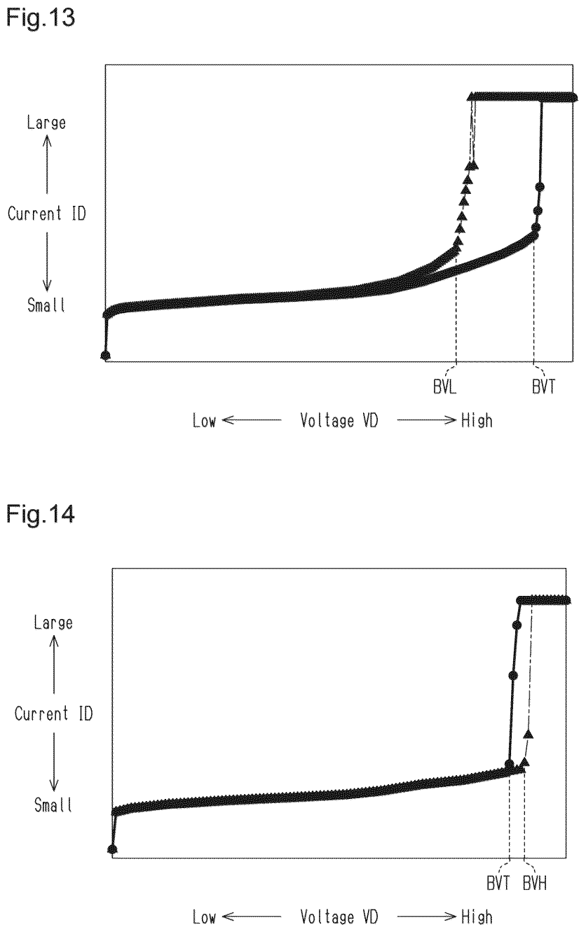

FIG. 13 is a graph showing the I-V characteristics of the comparative semiconductor device 10X. In FIG. 13, the horizontal axis represents a drain-source voltage VD applied to the drain of the comparative semiconductor device 10X, and the vertical axis represents a current ID flowing to the drain of the comparative semiconductor device 10X. In the graph, the solid line with the plot of black dots shows the result of the first measurement of the I-V characteristics. In the graph, the single-dashed line with the plot of triangles shows the result of the second measurement of the I-V characteristics.

In FIG. 13, voltage BVT refers to the drain-source breakdown voltage BV_{DSS} obtained at the time of the first measurement, and voltage BVL refers to the drain-source breakdown voltage BV_{DSS} obtained at the time of the second measurement. The voltage BVL is lower than the voltage BVT. This indicates occurrence of the walk-in phenomenon in the comparative semiconductor device 10X. For example, at a corner portion where the first peripheral gate trench portion 38A and the second peripheral gate trench portion 38B are curved, the depletion layer spreads differently from a linear portion of the first peripheral gate trench portion 38A and the second peripheral gate trench portion 38B extending in the X-axis direction or the Y-axis direction. Thus, the drain-source current flowing through the corner portion differs from the drain-source current flowing through the linear portion. As a result, after the first measurement of the drain-source breakdown voltage BV_{DSS}, the breakdown voltage property of the corner portion has deteriorated as compared to that of the linear portion. This may cause the drain-source breakdown voltage BV_{DSS} to be decreased at the time of the second measurement.

FIG. 14 is a graph showing the I-V characteristics of the semiconductor device 10 of the present embodiment. In FIG. 14, the horizontal axis represents a drain-source voltage VD applied to the drain of the semiconductor device 10 in the present embodiment, and the vertical axis represents a current ID flowing to the drain of the semiconductor device 10 in the present embodiment. In the graph, the solid line with the plot of black dots shows the result of the first measurement of the I-V characteristics. In the graph, the single-dashed line with the plot of triangles shows the result of the second measurement of the I-V characteristics.

In FIG. 14, voltage BVT refers to the drain-source breakdown voltage BV_{DSS} obtained at the time of the first measurement, and voltage BVH refers to the drain-source breakdown voltage BV_{DSS} obtained at the time of the second measurement. The voltage BVH is higher than the voltage BVT. This indicates occurrence of a walk-out phenomenon in the semiconductor device 10 of the present embodiment. In other words, the walk-in phenomenon does not occur in the semiconductor device 10 of the present embodiment. It is considered that the first floating trench 52A limits the deterioration of the breakdown voltage property at the corner portion, in which the first peripheral gate trench portion 38A and the second peripheral gate trench portion 38B are curved, after the first measurement of the drain-source breakdown voltage BV_{DSS}. Thus, formation of the first floating trench 52A (first floating electrode 80A) between the first peripheral gate trench portion 38A and the second peripheral gate trench portion 38B limits occurrence of the walk-in phenomenon.

### Advantages

The semiconductor device 10 of the present embodiment has the following advantages.

(1-1) The semiconductor device 10 includes the semiconductor layer 26, the gate trench 36 formed in the semiconductor layer 26, the insulation layer 60 formed on the semiconductor layer 26, the gate electrode 62 embedded in the gate trench 36 via the insulation layer 60, and the gate interconnect 22 formed on the insulation layer 60 and electrically connected to the gate electrode 62. The semiconductor layer 26 includes the peripheral region 28 including the edge of the semiconductor layer 26 in plan view and the active region 30 surrounded by the peripheral region 28. The peripheral gate trench portion 38 is arranged in the peripheral region 28. The peripheral gate trench portion 38 includes the first peripheral gate trench portion 38A and the second peripheral gate trench portion 38B arranged outward from the first peripheral gate trench portion 38A. The semiconductor device 10 includes the first floating trench 52A formed in the semiconductor layer 26 between the first peripheral gate trench portion 38A and the second peripheral gate trench portion 38B and the first floating electrode 80A embedded in the first floating trench 52A via the insulation layer 60. The first floating electrode 80A is electrically floating.

The walk-in phenomenon occurs in the comparative semiconductor device 10X, which does not include the first floating trench 52A and the first floating electrode 80A. In contrast, the walk-out phenomenon occurs in the semiconductor device 10 of the present embodiment, which includes the first floating trench 52A and the first floating electrode 80A. Thus, the semiconductor device 10 of the present embodiment limits occurrence of the walk-in phenomenon.

(1-2) The semiconductor device 10 further includes the protective trench 44 formed in the peripheral region 28. The first floating trench 52A is greater in width than the protective trench 44. The first floating insulation film 82A, which is the portion of the insulation layer 60 formed in the first floating trench 52A, is greater in thickness than the protective insulation film 78, which is the portion of the insulation layer 60 formed in the protective trench 44.

With this structure, the thickness of the first floating insulation film 82A is increased. This reduces the concentration of electric field on a corner obtained by bending the first floating trench 52A in plan view. Thus, the breakdown voltage of the semiconductor device 10 is improved.

(1-3) The first floating trench 52A is arranged closer to the second peripheral gate trench portion 38B than to the first peripheral gate trench portion 38A.

In this structure, the distance DGF11 between the first floating trench 52A and the first peripheral gate trench portion 38A is increased, whereas the distance DGF12 between the first floating trench 52A and the second peripheral gate trench portion 38B is decreased. As a result, as shown in the graphs of FIGS. 10 and 11, the drain-source breakdown voltage BV_{DSS} is increased.

(1-4) Each of the first peripheral gate trench portion 38A and the second peripheral gate trench portion 38B is greater in width than the protective trench 44.

In this structure, the gate insulation film 64, which is formed in the peripheral gate trench portions 38A and 38B, may be greater in thickness than the protective insulation film 78, which is formed in the protective trench 44. This reduces the concentration of electric field on a corner obtained by bending the peripheral gate trench portions 38A and 38B in plan view. Thus, the breakdown voltage of the semiconductor device 10 is improved.

(1-5) The peripheral electrode 24 is separated from the gate interconnect 22 and surrounds the gate interconnect 22.

This structure reduces the concentration of electric field on the region surrounded by the peripheral electrode 24, thereby improving the breakdown voltage of the semiconductor device 10.

(1-6) The distance DGF22 between the second peripheral gate trench portion 38B and the second floating trench 52B may be less than the distance DGF11 between the first peripheral gate trench portion 38A and the first floating trench 52A.

With this structure, as shown in the graph of FIG. 9, even when the distance DGF22 is decreased, the drain-source breakdown voltage BV_{DSS} is substantially constant. The decrease in the distance DGF22 allows for reduction in the size of the semiconductor device 10 while limiting a decrease in the drain-source breakdown voltage BV_{DSS}.

(1-7) The distance DGF11 between the first peripheral gate trench portion 38A and the first floating trench 52A may be greater than or equal to 4.56 μm.

With this structure, as shown in the graph of FIG. 10, when the distance DGF11 is less than 4.56 μm and the distance DGF11 is decreased, the drain-source breakdown voltage BV_{DSS} is decreased. When the distance DGF11 is greater than or equal to 4.56 μm, the drain-source breakdown voltage BV_{DSS} is substantially constant. Thus, when the distance DGF11 greater than or equal to 4.56 μm, a decrease in the drain-source breakdown voltage BV_{DSS} is limited. Moreover, when the distance DGF11 is approximately 4.56 μm, a decrease in the drain-source breakdown voltage BV_{DSS} is limited, while allowing for reduction in the size of the semiconductor device 10.

### Second Embodiment

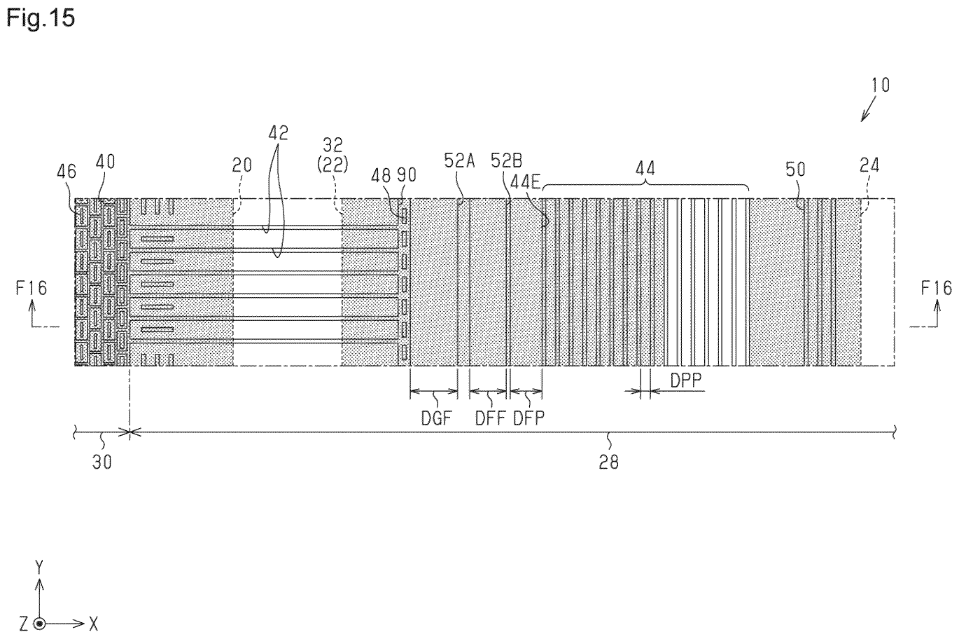

A second embodiment of a semiconductor device 10 will now be described with reference to FIGS. 15 to 20. The semiconductor device 10 of the second embodiment differs from the semiconductor device 10 of the first embodiment in the structure of the peripheral gate trench portion 38 and the structure between the connection gate trench portion 42 and the protective trench 44. In the description, differences from the semiconductor device 10 of the first embodiment will be described in detail. Same reference signs are given to those elements that are the same as the corresponding elements of the semiconductor device 10 of the first embodiment. Such elements will not be described in detail.

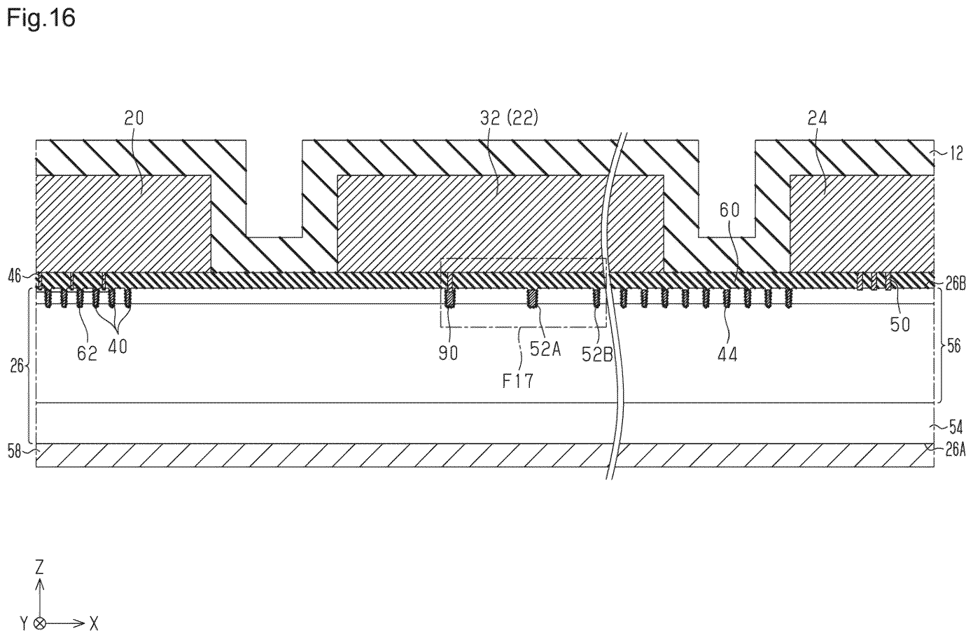

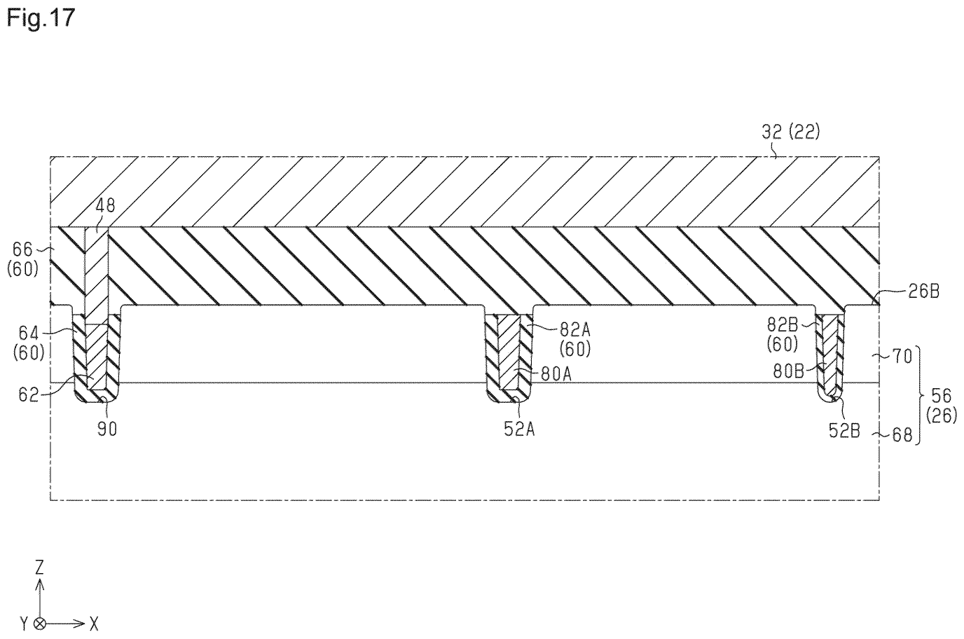

As shown in FIG. 15, the semiconductor device 10 of the present embodiment includes a peripheral gate trench portion 90 instead of the peripheral gate trench portion 38 (refer to FIG. 4). The peripheral gate trench portion 90 corresponds to the first peripheral gate trench portion 38A (refer to FIG. 4) of the first embodiment. Therefore, in the present embodiment, the semiconductor device 10 does not include the second peripheral gate trench portion 38B (refer to FIG. 4). The peripheral gate trench portion 90 is arranged in the peripheral region 28 and is surrounded by the protective trench 44 in plan view. As shown in FIGS. 16 and 17, the peripheral gate trench portion 90 has the same structure as the first peripheral gate trench portion 38A. Hence, the same reference signs are given to those elements that are the same as the corresponding elements of the first peripheral gate trench portion 38A. Such elements will not be described in detail.

As shown in FIG. 15, in the present embodiment, the gate trench 36 may include the inner gate trench portion 40, the connection gate trench portion 42, and the peripheral gate trench portion 90. The connection gate trench portion 42 connects the inner gate trench portion 40 and the peripheral gate trench portion 90.

The first floating trench 52A and the second floating trench 52B are arranged between the peripheral gate trench portion 90 and the protective trench 44. The second floating trench 52B is arranged outward from the first floating trench 52A. The second floating trench 52B and the peripheral gate trench portion 90 are arranged at opposite sides of the first floating trench 52A. In an example, the second floating trench 52B is arranged between the first floating trench 52A and the end protective trench 44E. The first floating trench 52A is arranged between the peripheral gate trench portion 90 and the second floating trench 52B.

In the example shown in FIG. 15, the first floating trench 52A is arranged closer to the second floating trench 52B than to the peripheral gate trench portion 90. In other words, a distance DGF between the peripheral gate trench portion 90 and the first floating trench 52A is greater than the distance DFF between the first floating trench 52A and the second floating trench 52B. In an example, the distance DGF may be in a range of 2 μm to 4.6 μm. In an example, the distance DFF may be in a range of 1 μm to 3.7 μm.

In another example, the distance DGF may be less than the distance DFF. That is, the first floating trench 52A may be arranged closer to the peripheral gate trench portion 90 than to the second floating trench 52B. In another example, the distance DGF may be equal to the distance DFF.

Each of the distance DGF and the distance DFF may be greater than the distance DPP between ones of the protective trenches 44 that are located next to each other. In an example, the distance DGF is greater than or equal to two times the distance DPP. In an example, the distance DGF is greater than or equal to three times the distance DPP. In an example, the distance DGF is less than or equal to four times the distance DPP. In an example, the distance DFF is greater than or equal to two times the distance DPP. In an example, the distance DFF is greater than or equal to three times the distance DPP. In an example, the distance DFF is greater than or equal to four times the distance DPP. In an example, the distance DFF is less than or equal to five times the distance DPP.

The distance DGF may be greater than the distance DFP between the second floating trench 52B and the end protective trench 44E. In another example, the distance DGF may be equal to the distance DFP or may be less than the distance DFP. The distance DFF may be less than the distance DFP. In another example, the distance DFF may be equal to the distance DFP or may be greater than the distance DFP.

The floating trenches 52A and 52B may be shaped to surround the peripheral gate trench portion 90 in plan view. In an example, the floating trenches 52A and 52B may be similar in shape to the peripheral gate trench portion 90 in plan view in the peripheral region 28. Thus, the first floating trench 52A may be closed-loop-shaped in conformance with the shape of the recess 20A (refer to FIG. 2) in plan view.

The floating trenches 52A and 52B are arranged so as not to overlap the gate finger 32 and the gate pad 34 in plan view. Also, the floating trenches 52A and 52B do not overlap the source interconnect 20 in plan view. That is, the floating trenches 52A and 52B are arranged between the source interconnect 20 and the gate finger 32 and between the source interconnect 20 and the gate pad 34 in plan view.

As shown in FIG. 17, in the same manner as in the first embodiment, the first floating electrode 80A and the first floating insulation film 82A are arranged in the first floating trench 52A. In the same manner as the first embodiment, the second floating electrode 80B and the second floating insulation film 82B are arranged in the second floating trench 52B.

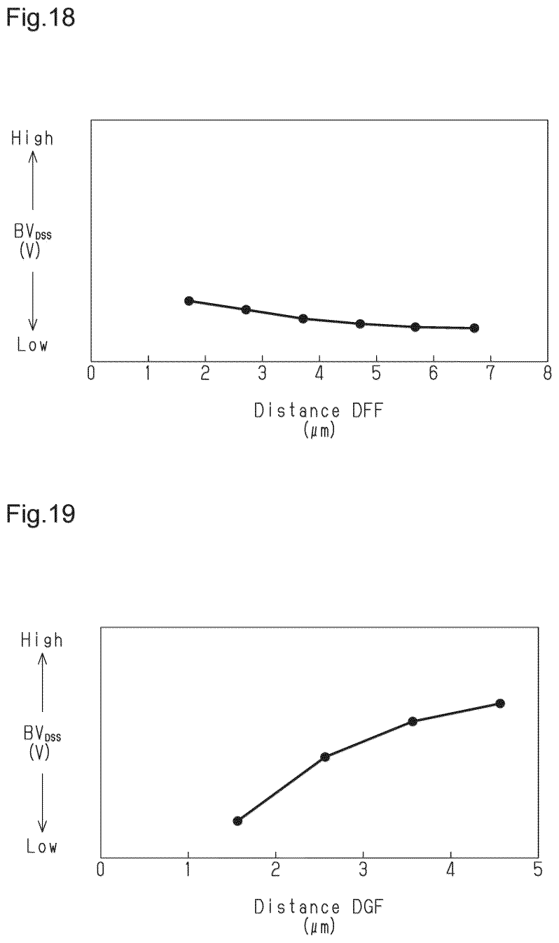

With reference to FIGS. 18 and 19, the relationship between the drain-source breakdown voltage BV_{DSS} and the positional relationship of the peripheral gate trench portion 90 with the floating trenches 52A and 52B will be described.

FIG. 18 is a graph showing the relationship of the drain-source breakdown voltage BV_{DSS} with the distance DFF between the first floating trench 52A and the second floating trench 52B. As shown in FIG. 18, as the distance DFF decreases, the drain-source breakdown voltage BV_{DSS} increases. Therefore, it is preferred that the distance DFF be small in the range of 1 μm to 3.7 μm, which is described above.

FIG. 19 is a graph showing the relationship of the drain-source breakdown voltage BV_{DSS} and the distance DGF between the peripheral gate trench portion 90 and the first floating trench 52A. FIG. 19 is a graph showing the relationship of the drain-source breakdown voltage BV_{DSS} with the distance DGF when the distance DFF is set to 3.72 μm.

As shown in FIG. 19, as the distance DGF increases, the drain-source breakdown voltage BV_{DSS} increases. The result indicates that it is preferred that the distance DGF is increased to increase the drain-source breakdown voltage BV_{DSS}. From the results shown in FIGS. 18 and 19, it is preferred that the first floating trench 52A is arranged closer to the second floating trench 52B than to the peripheral gate trench portion 90 in order to increase the drain-source breakdown voltage BV_{DSS}.

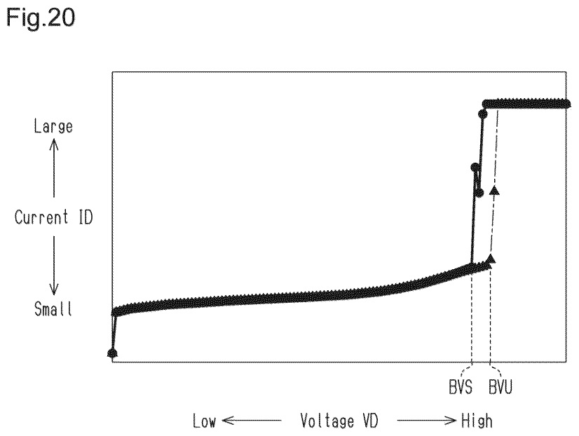

FIG. 20 is a graph showing the I-V characteristics of the semiconductor device 10 of the present embodiment. In FIG. 20, the horizontal axis represents a drain-source voltage VD applied to the drain of the semiconductor device 10 in the present embodiment, and the vertical axis represents a current ID flowing to the drain of the semiconductor device 10 in the present embodiment. In the graph, the solid line with the plot of black dots shows the result of the first measurement of the I-V characteristics. In the graph, the single-dashed line with the plot of triangles shows the result of the second measurement of the I-V characteristics.

In FIG. 20, voltage BVS refers to the drain-source breakdown voltage BV_{DSS} obtained at the time of the first measurement, and voltage BVU refers to the drain-source breakdown voltage BV_{DSS} obtained at the time of the second measurement. The voltage BVU is higher than the voltage BVS. This indicates occurrence of the walk-out phenomenon in the semiconductor device 10 of the present embodiment. In other words, the walk-in phenomenon does not occur in the semiconductor device 10 of the present embodiment. Thus, formation of the first floating trench 52A (first floating electrode 80A) between the peripheral gate trench portion 90 and the protective trench 44 limits occurrence of the walk-in phenomenon.

Moreover, the voltage BVS is lower than the voltage BVT, which is the drain-source breakdown voltage BV_{DSS} obtained at the time of the first measurement of the semiconductor device 10 in the first embodiment. The voltage BVU is lower than the voltage BVH, which is the drain-source breakdown voltage BV_{DSS} obtained at the time of the second measurement of the semiconductor device 10 in the first embodiment.

### Advantages

The semiconductor device 10 of the present embodiment has the following advantages in addition to the advantage (1-5) of the first embodiment.

(2-1) The semiconductor device 10 includes the semiconductor layer 26, the gate trench 36 formed in the semiconductor layer 26, the insulation layer 60 formed on the semiconductor layer 26, the gate electrode 62 embedded in the gate trench 36 via the insulation layer 60, the gate interconnect 22 formed on the insulation layer 60 and electrically connected to the gate electrode 62, the protective trenches 44 formed in the semiconductor layer 26, and the protective electrode 76 embedded in each protective trench 44 via the insulation layer 60. The semiconductor layer 26 includes the peripheral region 28 including the edge of the semiconductor layer 26 in plan view and the active region 30 surrounded by the peripheral region 28. The protective trench 44 is arranged in the peripheral region 28. The gate trench 36 includes the peripheral gate trench portion 90 arranged in the peripheral region 28 and surrounded by the protective trench 44 in plan view. The semiconductor device 10 includes the first floating trench 52A and the second floating trench 52B, which are formed in the semiconductor layer 26 between the peripheral gate trench portion 90 and the protective trench 44, the first floating electrode 80A embedded in the first floating trench 52A via the insulation layer 60 and being electrically floating, and the second floating electrode 80B embedded in the second floating trench 52B via the insulation layer 60 and being electrically floating. The first floating trench 52A is arranged closer to the second floating trench 52B than to the peripheral gate trench portion 90.

With this structure, as shown in the graph of FIG. 20, the walk-out phenomenon occurs due to the first floating trench 52A and the first floating electrode 80A. This limits occurrence of the walk-in phenomenon in the semiconductor device 10 of the present embodiment.

(2-2) The first floating trench 52A is greater in width than the protective trench 44. The first floating insulation film 82A, which is the portion of the insulation layer 60 formed in the first floating trench 52A, is greater in thickness than the protective insulation film 78, which is the portion of the insulation layer 60 formed in the protective trench 44.

In this structure, the thickness of the first floating insulation film 82A is increased to reduce the concentration of electric field on a corner obtained by bending the first floating trench 52A in plan view. Thus, the breakdown voltage of the semiconductor device 10 is improved.

(2-3) The peripheral gate trench portion 90 is greater in width than the protective trench 44.

In this structure, the gate insulation film 64, which is formed in the peripheral gate trench portion 90, may be greater in thickness than the protective insulation film 78, which is formed in the protective trench 44. This reduces the concentration of electric field on a corner obtained by bending the peripheral gate trench portion 90 in plan view. Thus, the breakdown voltage of the semiconductor device 10 is improved.

### Modified Examples

The embodiments described above may be modified as follows.

In the embodiments, the peripheral gate trench portions 38A and 38B may be formed in the peripheral region 28 and may be closed-loop-shaped along the four sides 26X1, 26X2, 26Y1, and 26Y2 of the semiconductor layer 26.

In the embodiments, the protective trench 44 may be formed in the peripheral region 28 and may be closed-loop-shaped along the four sides 26X1, 26X2, 26Y1, and 26Y2 of the semiconductor layer 26. That is, the protective trench 44 may extend along the four sides 26X1, 26X2, 26Y1, and 26Y2 of the semiconductor layer 26.

In the embodiments, the floating trenches 52A and 52B may be formed in the peripheral region 28 and may be closed-loop-shaped along the four sides 26X1, 26X2, 26Y1, and 26Y2 of the semiconductor layer 26.

In the embodiments, the peripheral electrode 24 may be omitted.

In the embodiments, the protective trench 44, the protective electrode 76, and the protective insulation film 78 may be omitted.

In the embodiments, the position of the gate pad 34 may be changed in any manner. In an example, the gate pad 34 may be arranged on any of the four corners of the semiconductor layer 26 in plan view.

In the embodiment, the conductivity type of each region in the semiconductor layer 26 may be reversed. More specifically, a p-type region may be changed to an n-type region, and an n-type region may be changed to a p-type region.

One or more of the various examples described in this specification may be combined within a range where there is no technical inconsistency.

In this specification, “at least one of A and B” should be understood to mean “only A, only B, or both A and B”.

In this specification, the term “on” includes the meaning of “above” in addition to the meaning of “on” unless otherwise clearly indicated in the context. Therefore, the phrase “first layer formed on second layer” is intended to mean that the first layer may be formed on the second layer in contact with the second layer in one embodiment and that the first layer may be located above the second layer without contacting the second layer in another embodiment. Thus, the word “on” will also allow for a structure in which another layer is arranged between the first layer and the second layer.

The directional terms used in this specification such as “vertical,” “horizontal,” “above,” “below,” “top,” “bottom,” “frontward,” “backward,” “lateral,” “left,” “right,” “front,” and “back” will depend upon a particular orientation of the device being described and illustrated. The present disclosure may include various alternative orientations. Therefore, the directional terms should not be narrowly construed.

In an example, the Z-axis direction referred to in this specification does not necessarily have to be the vertical direction and does not necessarily have to fully coincide with the vertical direction. In the structures according to the present disclosure (e.g., the structure shown in FIG. 5), “upward” and “downward” in the Z-axis direction as referred to in the present description are not limited to “upward” and “downward” in the vertical direction. For example, the X-axis direction may be the vertical direction. Alternatively, the Y-axis direction may be the vertical direction.

### Clauses

The technical aspects that are understood from the present disclosure will hereafter be described. It should be noted that, for the purpose of facilitating understanding with no intention to limit, elements described in clauses are given the reference characters of the corresponding elements of the embodiments. The reference signs are used as examples to facilitate understanding, and the elements in each clause are not limited to those elements given with the reference signs.

### Clause 1

A semiconductor device (10), including:
a semiconductor layer (26);
a gate trench (36) formed in the semiconductor layer (26);
an insulation layer (60) formed on the semiconductor layer (26);
a gate electrode (62) embedded in the gate trench (36) via the insulation layer (60);
a gate interconnect (22) formed on the insulation layer (60) and electrically connected to the gate electrode (62);
a first floating trench (52A); and
a floating electrode (80A) embedded in the first floating trench (52A) via the insulation layer (60), the floating electrode (80A) being electrically floating, in which
the semiconductor layer (26) includes a peripheral region (28) including an edge of the semiconductor layer (26) in plan view,
the gate trench (36) includes
   a first peripheral gate trench portion (38A) arranged in the peripheral region (28), and
   a second peripheral gate trench portion (38B) arranged outward from the first peripheral gate trench portion (38A), and
the first floating trench (52A) is formed in a region of the semiconductor layer (26) located between the first peripheral gate trench portion (38A) and the second peripheral gate trench portion (38B).

### Clause 2

The semiconductor device according to clause 1, further including:
a protective trench (44) arranged outward from the second peripheral gate trench portion (38B), in which
the first floating trench (52A) is greater in width than the protective trench (44), and
a portion (82A) of the insulation layer (60) formed in the first floating trench (52A) is greater in thickness than a portion (78) of the insulation layer (60) formed in the protective trench (44).

### Clause 3

The semiconductor device according to clause 1 or 2, in which the first floating trench (52A) is arranged closer to the second peripheral gate trench portion (38B) than to the first peripheral gate trench portion (38A).

### Clause 4

The semiconductor device according to any one of clauses 1 to 3, further including:
a protective trench (44) formed in the peripheral region (28); and
a second floating trench (52B) arranged between the second peripheral gate trench portion (38B) and the protective trench (44).

### Clause 5

The semiconductor device according to clause 4, in which
the first floating trench (52A) is greater in width than the second floating trench (52B), and
a portion (82A) of the insulation layer (60) formed in the first floating trench (52A) is greater in thickness than a portion (82B) of the insulation layer (60) formed in the second floating trench (52B).

### Clause 6

The semiconductor device according to any one of clauses 1 to 5, further including:
protective trenches (44) formed in the peripheral region (28),
in which a distance (DFF) between the second floating trench (52B) and the first floating trench (52A) is greater than a distance (DPP) between two of the protective trenches (44) located next to each other.

### Clause 7

The semiconductor device according to clause 4 or 5, in which
the protective trench (44) includes multiple protective trenches (44), and
a distance (DGF22) between the second peripheral gate trench portion (38B) and the second floating trench (52B) is greater than a distance (DPP) between two of the protective trenches (44) that are located next to each other.

### Clause 8

The semiconductor device according to any one of clauses 4, 5, and 7, in which
the protective trench (44) includes multiple protective trenches (44),
the protective trenches (44) include an end protective trench (44E), which is one of the protective trenches (44) that is located adjacent to the second floating trench (52B), and
a distance (DFP) between the second floating trench (52B) and the end protective trench (44E) is greater than a distance (DPP) between two of the protective trenches (44) that are located next to each other.

### Clause 9

The semiconductor device according to any one of clauses 1 to 8, in which
the semiconductor layer (26) includes an active region (30) surrounded by the peripheral region (28), and
the gate trench (36) includes
an inner gate trench (40) arranged in the active region (30), and
a connection trench (42) connecting the inner gate trench (40) and the first peripheral gate trench portion (38A).

### Clause 10

A semiconductor device (10), including:
a semiconductor layer (26);
a gate trench (36) formed in the semiconductor layer (26);
an insulation layer (60) formed on the semiconductor layer (26);
a gate electrode (62) embedded in the gate trench (36) via the insulation layer (60);
a gate interconnect (22) formed on the insulation layer (60) and electrically connected to the gate electrode (62);
a protective trench (44) formed in the semiconductor layer (26);
a protective electrode (78) embedded in the protective trench (44) via the insulation layer (60);
a first floating trench (52A) and a second floating trench (52B);
a first floating electrode (80A) embedded in the first floating trench (52A) via the insulation layer (60), the first floating electrode (80A) being electrically floating; and
a second floating electrode (80B) embedded in the second floating trench (52B) via the insulation layer (60), the second floating electrode (80B) being electrically floating, in which
the semiconductor layer (26) includes a peripheral region (28) including an edge of the semiconductor layer (26) in plan view, the protective trench (44) being formed in the peripheral region (28),
the gate trench (36) includes a peripheral gate trench portion (90) arranged in the peripheral region (28) and surrounded by the protective trench (44) in plan view,
the first floating trench (52A) and the second floating trench (52B) are formed in a region of the semiconductor layer (26) located between the peripheral gate trench portion (90) and the protective trench (44), and
the first floating trench (52A) is arranged closer to the second floating trench (52B) than to the peripheral gate trench portion (90).

### Clause 11

The semiconductor device according to clause 10, in which
the first floating trench (52A) is greater in width than the protective trench (44), and
a portion (82A) of the insulation layer (60) formed in the first floating trench (52A) is greater in thickness than a portion (78) of the insulation layer (60) formed in the protective trench (44).

### Clause 12

The semiconductor device according to clause 10 or 11, in which
the peripheral gate trench portion (90) is greater in width than the protective trench (44), and
a portion (64) of the insulation layer (60) formed in the peripheral gate trench portion (90) is greater in thickness than a portion (78) of the insulation layer (60) formed in the protective trench (44).

### Clause 13

The semiconductor device according to any one of clauses 10 to 12, in which
the first floating trench (52A) is equal in width to the peripheral gate trench portion (90), and
a portion (82A) of the insulation layer (60) formed in the first floating trench (52A) is equal in thickness to a portion (64) of the insulation layer (60) formed in the peripheral gate trench portion (90).

### Clause 14

The semiconductor device according to any one of clauses 10 to 13, in which
the first floating trench (52A) is greater in width than the second floating trench (52B), and
a portion (82A) of the insulation layer (60) formed in the first floating trench (52A) is greater in thickness than a portion (82B) of the insulation layer (60) formed in the second floating trench (52B).

### Clause 15

The semiconductor device according to any one of clauses 10 to 14, in which
the protective trench (44) includes multiple protective trenches (44), and
a distance (DGF) between the peripheral gate trench portion (90) and the first floating trench (52A) is greater than a distance (DPP) between two of the protective trenches (44) located next to each other.

### Clause 16

The semiconductor device according to any one of clauses 10 to 15, in which
the protective trench (44) includes multiple protective trenches (44), and
a distance (DFF) between the first floating trench (52A) and the second floating trench (52B) is greater than a distance (DPP) between two of the protective trenches (44) located next to each other.

### Clause 17

The semiconductor device according to any one of clauses 10 to 16, in which
the protective trench (44) includes multiple protective trenches (44),
the protective trenches (44) include an end protective trench (44E), which is one of the protective trenches (44) that is located adjacent to the second floating trench (52B), and
a distance (DFP) between the second floating trench (52B) and the end protective trench (44E) is greater than a distance (DPP) between two of the protective trenches (44) that are located next to each other.

### Clause 18

The semiconductor device according to any one of claims 10 to 17, in which
the semiconductor layer (26) includes an active region (30),
the gate trench (36) includes
   an inner gate trench (40) arranged in the active region (30), and
   a connection trench (42) connecting the inner gate trench (40) and the peripheral gate trench portion (90).

### Clause 19

The semiconductor device according to any one of clauses 2, and 4 to 8, in which
each of the first peripheral gate trench portion (38A) and the second peripheral gate trench portion (38B) is greater in width than the protective trench (44).

### Clause 20

The semiconductor device according to any one of clauses 1 to 19, further including:
a peripheral electrode (24) formed on the insulation layer (60) and separated from the gate interconnect (22),
in which the peripheral electrode (24) surrounds the gate interconnect (22).

The description above illustrates examples. One skilled in the art may recognize further possible combinations and replacements of the elements and methods (manufacturing processes) in addition to those listed for purposes of describing the techniques of the present disclosure. The present disclosure is intended to include any substitute, modification, changes included in the scope of the disclosure including the claims.

1. A semiconductor device, comprising:
a semiconductor layer;
a gate trench formed in the semiconductor layer;
an insulation layer formed on the semiconductor layer;
a gate electrode embedded in the gate trench via the insulation layer;
a gate interconnect formed on the insulation layer and electrically connected to the gate electrode;
a first floating trench; and
a floating electrode embedded in the first floating trench via the insulation layer, the floating electrode being electrically floating, wherein
the semiconductor layer includes a peripheral region including an edge of the semiconductor layer in plan view,
the gate trench includes
a first peripheral gate trench portion arranged in the peripheral region, and
a second peripheral gate trench portion arranged outward from the first peripheral gate trench portion, and
the first floating trench is formed in a region of the semiconductor layer located between the first peripheral gate trench portion and the second peripheral gate trench portion.

2. The semiconductor device according to claim 1, further comprising:
a protective trench arranged outward from the second peripheral gate trench portion, wherein
the first floating trench is greater in width than the protective trench, and
a portion of the insulation layer formed in the first floating trench is greater in thickness than a portion of the insulation layer formed in the protective trench.

3. The semiconductor device according to claim 1, wherein the first floating trench is arranged closer to the second peripheral gate trench portion than to the first peripheral gate trench portion.

4. The semiconductor device according to claim 1, further comprising:
a protective trench formed in the peripheral region; and
a second floating trench arranged between the second peripheral gate trench portion and the protective trench.

5. The semiconductor device according to claim 4, wherein
the first floating trench is greater in width than the second floating trench, and
a portion of the insulation layer formed in the first floating trench is greater in thickness than a portion of the insulation layer formed in the second floating trench.

6. The semiconductor device according to claim 1, further comprising:
protective trenches formed in the peripheral region,
wherein a distance between the second floating trench and the first floating trench is greater than a distance between two of the protective trenches located next to each other.

7. The semiconductor device according to claim 4, wherein
the protective trench includes multiple protective trenches, and
a distance between the second peripheral gate trench portion and the second floating trench is greater than a distance between two of the protective trenches that are located next to each other.

8. The semiconductor device according to claim 4, wherein
the protective trench includes multiple protective trenches,
the protective trenches include an end protective trench, which is one of the protective trenches that is located adjacent to the second floating trench, and
a distance between the second floating trench and the end protective trench is greater than a distance between two of the protective trenches that are located next to each other.

9. The semiconductor device according to claim 1, wherein
the semiconductor layer includes an active region surrounded by the peripheral region, and
the gate trench includes
an inner gate trench arranged in the active region, and
a connection trench connecting the inner gate trench and the first peripheral gate trench portion.

10. A semiconductor device, comprising:
a semiconductor layer;
a gate trench formed in the semiconductor layer;
an insulation layer formed on the semiconductor layer;
a gate electrode embedded in the gate trench via the insulation layer;
a gate interconnect formed on the insulation layer and electrically connected to the gate electrode;
a protective trench formed in the semiconductor layer;
a protective electrode embedded in the protective trench via the insulation layer;
a first floating trench and a second floating trench;
a first floating electrode embedded in the first floating trench via the insulation layer, the first floating electrode being electrically floating; and
a second floating electrode embedded in the second floating trench via the insulation layer, the second floating electrode being electrically floating, wherein
the semiconductor layer includes a peripheral region including an edge of the semiconductor layer in plan view, the protective trench being formed in the peripheral region,
the gate trench includes a peripheral gate trench portion arranged in the peripheral region and surrounded by the protective trench in plan view,
the first floating trench and the second floating trench are formed in a region of the semiconductor layer located between the peripheral gate trench portion and the protective trench, and
the first floating trench is arranged closer to the second floating trench than to the peripheral gate trench portion.

11. The semiconductor device according to claim 10, wherein
the first floating trench is greater in width than the protective trench, and
a portion of the insulation layer formed in the first floating trench is greater in thickness than a portion of the insulation layer formed in the protective trench.

12. The semiconductor device according to claim 10, wherein
the peripheral gate trench portion is greater in width than the protective trench, and
a portion of the insulation layer formed in the peripheral gate trench is greater in thickness than a portion of the insulation layer formed in the protective trench.

13. The semiconductor device according to claim 10, wherein
the first floating trench is equal in width to the peripheral gate trench portion, and
a portion of the insulation layer formed in the first floating trench is equal in thickness to a portion of the insulation layer formed in the peripheral gate trench portion.

14. The semiconductor device according to claim 10, wherein
the first floating trench is greater in width than the second floating trench, and
a portion of the insulation layer formed in the first floating trench is greater in thickness than a portion of the insulation layer formed in the second floating trench.

15. The semiconductor device according to claim 10, wherein
the protective trench includes multiple protective trenches, and
a distance between the peripheral gate trench portion and the first floating trench is greater than a distance between two of the protective trenches located next to each other.

16. The semiconductor device according to claim 10, wherein
the protective trench includes multiple protective trenches, and
a distance between the first floating trench and the second floating trench is greater than a distance between two of the protective trenches located next to each other.

17. The semiconductor device according to claim 10, wherein
the protective trench includes multiple protective trenches,
the protective trenches include an end protective trench, which is one of the protective trenches that is located adjacent to the second floating trench, and
a distance between the second floating trench and the end protective trench is greater than a distance between two of the protective trenches that are located next to each other.

18. The semiconductor device according to claim 10, wherein
the semiconductor layer includes an active region,
the gate trench includes
an inner gate trench arranged in the active region, and
a connection trench connecting the inner gate trench and the peripheral gate trench portion.
